(19) United States
(12) Patent Application Publication
(10) Pub. No.: US 2026/0173720 A1
(43) Pub. Date: Jun. 18, 2026

(54) DISPLAY PANEL AND DISPLAY DEVICE

(71) Applicants: Kunshan Govisionox Optoelectronics Co., Ltd., Kunshan (CN); Hefei Visionox Technology Co., Ltd., Hefei (CN); Hefei Visionox Electronics Co., Ltd., Hefei (CN)

(72) Inventors: Chung-Chun LEE, Kunshan (CN); Yiming XIAO, Kunshan (CN); Yuan YAO, Kunshan (CN); Aihua XUE, Kunshan (CN)

(73) Assignees: Kunshan Govisionox Optoelectronics Co., Ltd., Kunshan (CN); Hefei Visionox Technology Co., Ltd., Hefei (CN); Hefei Visionox Electronics Co., Ltd., Hefei (CN)

(21) Appl. No.: 19/430,153

(22) Filed: Dec. 22, 2025

Related U.S. Application Data
(63) Continuation of application No. PCT/CN2025/132441, filed on Nov. 4, 2025.

(30) Foreign Application Priority Data
Dec. 13, 2024 (CN) 202411849695.0

(51) Int. Cl. H10K 59/80; H10K 59/122; H10K 59/131; H10K 59/35

(52) U.S. Cl. CPC H10K 59/8723; H10K 59/122; H10K 59/1315; H10K 59/352; H10K 59/353; H10K 59/873

(57) ABSTRACT

The present disclosure provides a display panel and a display device. In the display panel, a light-emitting structure of at least one light-emitting device includes a plurality of light-emitting sub-structures. An isolation layer includes a partition wall located between adjacent light-emitting sub-structures. An orthogonal projection of a first electrode of the at least one light-emitting device on the array substrate covers an orthogonal projection of the partition wall corresponding to the at least one light-emitting device on the array substrate and orthogonal projections of the plurality of light-emitting sub-structures corresponding to the at least one light-emitting device on the array substrate. The present disclosure may address display-defect issue.

### CROSS-REFERENCE TO RELATED APPLICATIONS

This application is a continuation of International Application No. PCT/CN2025/132441, filed on Nov. 4, 2025, which claims priority to Chinese Patent Application No. 2024118496950, filed on Dec. 13, 2024. The disclosures of the aforementioned applications are hereby incorporated by reference in their entireties.

### FIELD

The present disclosure generally relates to the field of semiconductor encapsulation technologies, and in particular, to a display panel and a display device.

### BACKGROUND

Organic Light Emitting Diode (OLED) display technology is regarded as the most promising new flat panel display technology for the next generation. Compared with liquid crystal display technology, OLED display technology has advantages such as low energy consumption, low cost, self-luminescence, wide viewing angle, and fast response speed.

In a traditional manufacturing process for a display panel, light-emitting pixel patterning is typically achieved through a Fine Metal Mask (FMM). FMM technology is mature and has extensive mass production experience. However, FMM technology also has issues such as limited precision, high development costs, and long development cycles. Fine Metal Mask-less technology eliminates the limitations of traditional OLED processes on display size, resolution, and other screen performance characteristics, offering advantages of high performance, full-size capability, and agile delivery. Patents CN118251982A, CN115666161A, CN116648095A, CN117062489A, CN118678742A, CN118785761A, CN115224220A, CN118678729A, CN118660529A, CN118660589A document relevant content of fine metal mask-free technology for reference.

However, current OLED display products still suffer from display defects.

### SUMMARY

In view of above, it is necessary to provide a display panel and a display device to solve aforementioned problems.

In a first aspect, embodiments of the present disclosure provide a display panel, including: an array substrate; an isolation layer located on a side of the array substrate and including an isolation structure and a plurality of isolation openings defined by the isolation structure, where the plurality of isolation openings include a plurality of first isolation openings, a plurality of second isolation openings, and a plurality of third isolation openings; and a plurality of light-emitting devices, including a plurality of first light-emitting devices arranged correspondingly to the plurality of first isolation openings, a plurality of second light-emitting devices arranged correspondingly to the plurality of second isolation openings, and a plurality of third light-emitting devices arranged correspondingly to the plurality of third isolation openings; the plurality of first light-emitting devices, the plurality of second light-emitting devices, and the plurality of third light-emitting devices are configured to emit light of different colors; a light-emitting device includes a first electrode, a light-emitting structure, and a second electrode sequentially stacked; where a light-emitting structure of at least one of the plurality of light-emitting devices includes a plurality of light-emitting sub-structures, the isolation layer includes a partition wall located between adjacent light-emitting sub-structures, an orthogonal projection of the first electrode of at least one of the plurality of light-emitting devices on the array substrate covers an orthogonal projection of the partition wall corresponding to the at least one of the plurality of light-emitting devices on the array substrate and orthogonal projections of the plurality of light-emitting sub-structures corresponding to the at least one of the plurality of light-emitting devices on the array substrate.

In the display panel provided by embodiments of the present disclosure, as the light-emitting structure of at least one light-emitting device includes a plurality of sub-structures and the orthogonal projection of the first electrode of the at least one light-emitting device is covers the orthogonal projection of each light-emitting sub-structure, a single light-emitting structure is separated into the plurality of light-emitting sub-structures electrically connected to the same driver circuit. In this way, when a certain light-emitting sub-structure fails, it may not affect other light-emitting sub-structures. The other light-emitting sub-structures may still emit light normally, thereby reducing the risk of display defects in the display panel. Furthermore, the orthogonal projection of the first electrode further covers the orthogonal projection of the corresponding partition wall, thereby enabling a larger coverage area for the first electrode. This is beneficial for reducing the resistance of the first electrode and thereby decreasing the power consumption of the display panel.

In a second aspect, embodiments of the present disclosure provide a display panel, including: an array substrate; a plurality of light-emitting unit groups arranged on the array substrate; where a light-emitting unit group includes a plurality of light-emitting structures, the plurality of light-emitting structures include a plurality of first light-emitting structures, a plurality of second light-emitting structures, and a plurality of third light-emitting structures, centroids of the plurality of second light-emitting structures and the plurality of third light-emitting structures, when connected, define a first virtual polygon, at least one of the plurality of first light-emitting structure is located in the first virtual polygon; the plurality of first light-emitting structures, the plurality of second light-emitting structures, and the plurality of third light-emitting structures are configured to emit light of different colors; and in a same light-emitting unit group, at least one of the plurality of light-emitting structures includes a plurality of light-emitting sub-structures spaced apart, the plurality of light-emitting sub-structures are electrically connected to the same driver circuit in the array substrate.

In a third aspect, embodiments of the present disclosure provide a display panel, including: an array substrate; a plurality of light-emitting unit groups arranged on the array substrate; where a light-emitting unit group includes a plurality of light-emitting structures, the plurality of light-emitting structures include a plurality of first light-emitting structures, a plurality of second light-emitting structures, and a plurality of third light-emitting structures, centroids of the plurality of second light-emitting structures and the plurality of third light-emitting structures, when connected, define a first virtual polygon, at least one of the plurality of first light-emitting structure is located in the first virtual polygon; the plurality of first light-emitting structures, the plurality of second light-emitting structures, and the plurality of third light-emitting structures are configured to emit light of different colors; and in a same light-emitting unit group, at least one of the plurality of light-emitting structures includes a plurality of light-emitting sub-structures spaced apart, the plurality of light-emitting sub-structures are electrically connected to the same driver circuit in the array substrate; and a distance between two adjacent light-emitting structures is a third spacing; in the same light-emitting structure, a distance between two adjacent light-emitting sub-structures is a fourth spacing, and the third spacing is equal to the fourth spacing.

In a fourth aspect, embodiments of the present disclosure provide a display device, including the display panel of any one embodiment of the first aspect, the second aspect, and the third aspect.

### BRIEF DESCRIPTION OF THE DRAWINGS

To more clearly illustrate the embodiments of the present disclosure or the prior art, a brief description of accompanying drawings that are required in the embodiments will hereinafter be provided. In one embodiment, the accompanying drawings described below are only some embodiments of the present disclosure.

FIG. 1 is a schematic top view of a display panel according to an embodiment of the present disclosure.

FIG. 2 is a schematic partial top view of a part of layers of the display panel shown in FIG. 1.

FIG. 3 is a schematic diagram of a sectional structure of section A-A in FIG. 2.

FIG. 4 is a schematic diagram of a sectional structure of section B-B in FIG. 2.

FIG. 5 is a schematic diagram of another sectional structure of section A-A in FIG. 2.

FIG. 6 is a schematic partial top view of a light-emitting structure of the display panel shown in FIG. 2.

FIG. 7 is a schematic partial top view of an isolation layer of the display panel shown in FIG. 2.

FIG. 8 is a schematic partial top view of a first electrode of the display panel shown in FIG. 2.

FIG. 9 is a schematic partial top view of the isolation layer in FIG. 7 and the first electrode in FIG. 8.

FIG. 10 is a schematic partial top view of a pixel defining layer of the display panel shown in FIG. 2.

FIG. 11 is a schematic partial top view of the isolation layer in FIG. 7 and the pixel defining layer in FIG. 10.

FIG. 12 is a schematic top view of an isolation structure and a first wiring line of the display panel shown in FIG. 1.

FIG. 13 is a schematic top view of a light-emitting structure and a first wiring line of the display panel shown in FIG. 1.

FIG. 14 is a schematic top view of an isolation layer of another display panel according to an embodiment of the present disclosure.

FIG. 15 is a schematic diagram of an arrangement of a light-emitting structure of the light-emitting device of the display panel shown in FIG. 14.

FIG. 16 is a schematic diagram of an arrangement of the light-emitting unit group shown in FIG. 15.

FIGS. 17A-17F are schematic diagrams of several separation methods according to an embodiment of the present disclosure for the arrangement pattern of the light-emitting structure shown in FIG. 14.

FIG. 18 is a schematic top view of an isolation layer of yet another display panel according to an embodiment of the present disclosure.

FIG. 19 is a schematic diagram of an arrangement of a light-emitting structure of the light-emitting device of the display panel shown in FIG. 18.

FIGS. 20A-20Q are schematic diagrams of several separation methods according to an embodiment of the present disclosure for the arrangement pattern of the light-emitting structure shown in FIG. 18.

FIG. 21 is a schematic top view of an isolation layer of still another display panel according to an embodiment of the present disclosure.

FIG. 22 is a schematic diagram of an arrangement of a light-emitting structure of the light-emitting device of the display panel shown in FIG. 21.

FIGS. 23A-23H are schematic diagrams of several separation methods according to an embodiment of the present disclosure for the arrangement pattern of the light-emitting structure shown in FIG. 21.

FIG. 24 is a schematic partial top view of an isolation layer of still another display panel according to an embodiment of the present disclosure.

FIG. 25A is a schematic partial top view of an isolation layer of still another display panel according to an embodiment of the present disclosure.

FIG. 25B is a schematic top view of a partial structure of a light-emitting device of the display panel shown in FIG. 25A.

FIG. 26A is a schematic partial top view of an isolation layer of still another display panel according to an embodiment of the present disclosure.

FIG. 26B is a schematic top view of a partial structure of a light-emitting device of the display panel shown in FIG. 26A.

FIG. 27 is a schematic top view of a partial structure of a light-emitting device of still another display panel according to an embodiment of the present disclosure.

FIG. 28 is a schematic top view of a partial structure of a light-emitting device of still another display panel according to an embodiment of the present disclosure.

FIG. 29 is a schematic top view of a light-emitting structure of still another display panel according to an embodiment of the present disclosure.

FIG. 30 is a schematic partial top view of an isolation layer of still another display panel according to an embodiment of the present disclosure.

FIG. 31 is a schematic top view of a partial structure of a light-emitting device of the display panel shown in FIG. 30.

FIG. 32 is a schematic partial top view of an isolation layer of still another display panel according to an embodiment of the present disclosure.

FIG. 33 is a schematic top view of a partial structure of a light-emitting device of the display panel shown in FIG. 32

FIG. 34 is another schematic top view of a partial structure of a light-emitting device of the display panel shown in FIG. 32.

FIG. 35 is a schematic partial top view of an isolation layer of still another display panel according to an embodiment of the present disclosure.

FIG. 36 is a schematic top view of a partial structure of the light-emitting device of the display panel shown in FIG. 35.

### DETAILED DESCRIPTION OF THE EMBODIMENTS

To facilitate understanding of the present disclosure, the following description will provide a more comprehensive overview with reference to relevant accompanying drawings.

Unless otherwise defined, all technical and scientific terms used herein have the same meaning as commonly understood in the art belonging to the field of the present disclosure. Terms used in the description of the present disclosure are for the purpose of describing specific embodiments only and is not intended to limit the present disclosure. The term “and/or” as used herein includes any and all combinations of one or more of the associated listed items.

In conventional technologies, the malfunction of one or more light-emitting devices in an OLED display panel may occur, resulting in display defects.

In view of above, embodiments of the present disclosure provide a display panel and a display device. On the one hand, when a certain light-emitting sub-structure fails, it may not affect other light-emitting sub-structures. The other light-emitting sub-structures may still emit light normally, thereby reducing the risk of display defects in the display panel. On the other hand, an orthogonal projection of a first electrode further covers an orthogonal projection of a partition wall corresponding to the first electrode, thereby enabling a larger coverage area for the first electrode. This is beneficial for reducing resistance of the first electrode and thereby decreasing power consumption of the display panel.

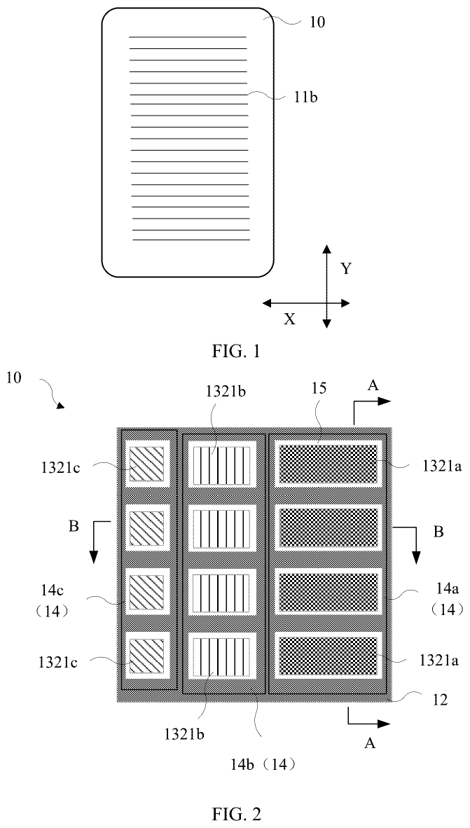

Referring to FIGS. 1 to 5, embodiments of the present disclosure provide a display panel 10. The display panel 10 may be, for example, an Organic Light Emitting Diode (OLED) display panel 10 or a Quantum Dot Light Emitting Diode (QLED) display panel 10.

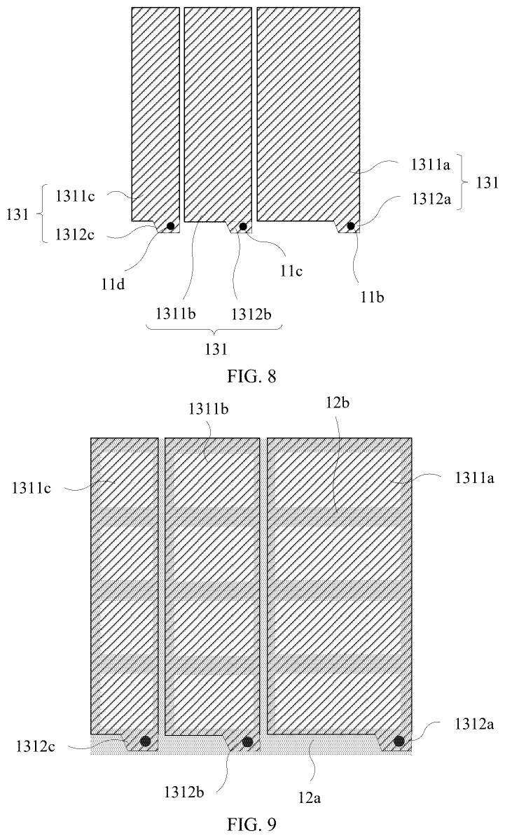

Specifically, the display panel 10 includes an array substrate 11, an isolation layer 12, and a plurality of light-emitting devices 13. As shown in FIGS. 2 and 7, the isolation layer 12 is located on a side of the array substrate 11, and includes an isolation structure 12a and a plurality of isolation openings 12c defined by the isolation structure 12a. The plurality of isolation openings 12c include a plurality of first isolation openings 12c-1, a plurality of second isolation openings 12c-2, and a plurality of third isolation openings 12c-3. As shown in FIGS. 2, 4, and 7, the plurality of light-emitting devices 13 includes a plurality of first light-emitting devices 13a arranged correspondingly to the plurality of first isolation openings 12c-1, a plurality of second light-emitting devices 13b arranged correspondingly to the plurality of second isolation openings 12c-2, and a plurality of third light-emitting devices 13c arranged correspondingly to the plurality of third isolation openings 12c-3. The first light-emitting device 13a, the second light-emitting device 13b, and the third light-emitting device 13c are configured to emit light of different colors. A light-emitting device 13 includes a first electrode 131, a light-emitting structure 132, and a second electrode 133 sequentially stacked. The first electrode 131 may be an anode and the second electrode 133 may be a cathode. Exemplarily, the first light-emitting devices 13a are in one-to-one correspondence with the first isolation openings 12c-1, the second light-emitting devices 13b are in one-to-one correspondence with the second isolation openings 12c-2, and the third light-emitting devices 13c are in one-to-one correspondence with the third isolation openings 12c-3.

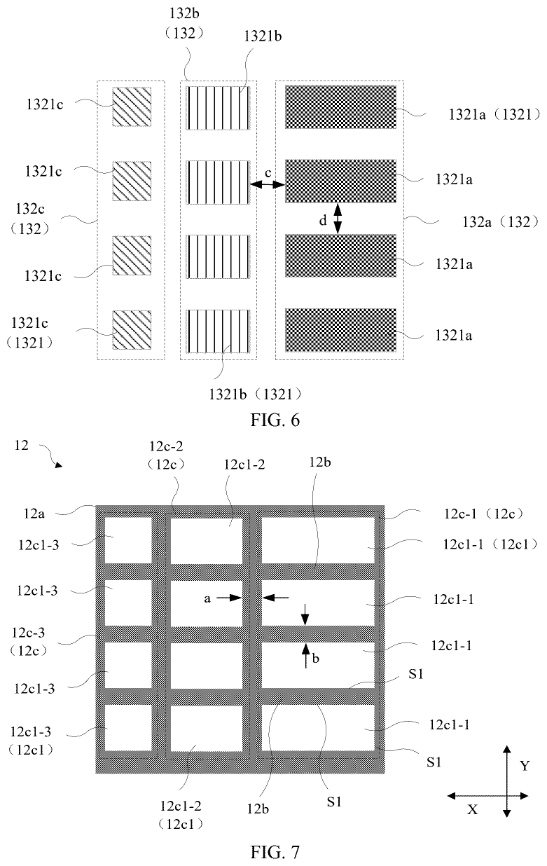

As shown in FIGS. 6, 7, 8, and 9, the light-emitting structure 132 of at least one light-emitting device 13 includes a plurality of light-emitting sub-structures 1321, the isolation layer 12 includes a partition wall 12b located between adjacent light-emitting sub-structures 1321. That is, the partition wall 12b separates the light-emitting structure 132 into a plurality of light-emitting sub-structures 1321.

An orthogonal projection of the first electrode 131 of the at least one light-emitting device 13 on the array substrate 11 covers an orthogonal projection of the partition wall 12b corresponding to the at least one light-emitting device 13 on the array substrate 11, and orthogonal projections of the plurality of light-emitting sub-structures 1321 corresponding to the at least one light-emitting device 13 on the array substrate 11.

In the display panel 10 provided by embodiments of the present disclosure, the light-emitting structure 132 of the at least one light-emitting device 13 includes a plurality of sub-structures 1321, and the orthogonal projection of the first electrode 131 of the at least one light-emitting device 13 covers the orthogonal projection of each light-emitting sub-structure 1321, so that a single light-emitting structure 132 is separated into the plurality of light-emitting sub-structures 1321 electrically connected to a same driver circuit through the partition wall 12b. Thus, when a certain light-emitting sub-structure 1321 fails (e.g., dark-spot failures caused by particle residues and encapsulation failures), it may not affect other light-emitting sub-structures 1321. The other light-emitting sub-structures 1321 may still emit light normally, thereby reducing the risk of display defects in the display panel 10. Furthermore, the orthogonal projection of the first electrode 131 further covers the orthogonal projection of the corresponding partition wall 12b, thereby enabling a larger coverage area for the first electrode 131. This is beneficial for reducing the resistance of the first electrode 131, thereby decreasing the power consumption of the display panel 10.

In one embodiment, in the plurality of first light-emitting devices 13a, the plurality of second light-emitting devices 13b, and the plurality of third light-emitting devices 13c, the light-emitting structure 132 of the light-emitting device 13 of at least one color include a plurality of light-emitting sub-structures 1321. Thus, the light-emitting structure 132 of the same color is separated into the plurality of light-emitting sub-structures 1321, thereby maintaining consistency among light-emitting structures 132 of the same color and improving display uniformity. Optionally, in the plurality of first light-emitting devices 13a, the plurality of second light-emitting devices 13b, and the plurality of third light-emitting devices 13c, the light-emitting structures 132 of the light-emitting devices 13 of at least two colors include the plurality of light-emitting sub-structures 1321. Thus, compared with the light-emitting structure 132 of only one color separated, the embodiment separates the light-emitting structures 132 of two colors so that the light-emitting structures 132 of two colors may overcome display defects (e.g., dark-spot failures caused by particle residues and encapsulation failures), further reducing the risk of poor display. Optionally, the light-emitting structure 132 of each of the plurality of light-emitting devices 13 includes the plurality of light-emitting sub-structures 1321. Thus, in this embodiment, the light-emitting structures 132 of three colors are separated so that the light-emitting structures 132 of the three colors may overcome display defects (e.g., dark-spot failures caused by particle residues and encapsulation failures), thereby further reducing the risk of poor display.

In one embodiment, as shown in FIG. 7, the isolation opening 12c corresponding to at least one light-emitting device 13 includes a plurality of sub-isolation openings 12c1. The partition wall 12b is arranged between two adjacent sub-isolation openings 12c1. The plurality of sub-isolation openings 12c1 are in one-to-one correspondence with the plurality of light-emitting sub-structures 1321. Thus, the partition wall 12b separates the isolation opening 12c into the plurality of sub-isolation openings 12c1.

In one embodiment, as shown in FIG. 7, in the orthogonal projection of the partition wall 12b on the array substrate 11, a projection edge S1 adjacent to one sub-isolation opening 12c1 is parallel to a projection edge S1 adjacent to another sub-isolation opening 12c1. Thus, a shape of the partition wall 12b may be made relatively regular, and at the same time, a space occupied by the partition wall 12b may be reduced. Furthermore, when a spacing between two sub-isolation openings 12c1 is fixed, space occupied by the two sub-isolation openings 12c1 may be maximized, thereby facilitating increasing an area occupied by the light-emitting sub-structure 1321 and further improving an aperture ratio. Due to the manufacturing process errors, the parallelism of A and B as described in the specification not only includes absolute parallelism but also approximate parallelism. Exemplarily, when an angle between A and B ranges from −5° to 5°, it may also be considered that A is parallel with B.

Optionally, as shown in FIG. 1, the array substrate 11 includes a plurality of scan lines 11b spaced apart along a second direction Y, each of the plurality of scan lines 11b extends along a first direction X intersecting the second direction Y. The orthogonal projection of the sub-isolation opening 12c1 on the array substrate 11 includes at least one projection edge S1 parallel to the second direction Y. That is, a part of side walls of the sub-isolation opening 12c1 is parallel to the second direction Y.

In some embodiments, the second electrode 133 needs to overlap with the isolation layer 12 (e.g., the isolation structure 12a or the partition wall 12b), so as to achieve an electrical connection between the second electrode 133 and the isolation layer 12. Furthermore, during the deposition of the second electrode 133, a deposition source is used to scan along the first direction X. The deposition material is more easily deposited onto a part of the side walls (the side wall parallel to the second direction Y) of the isolation layer 12, thereby enabling a better connection performance between the second electrode 133 and the isolation layer 12.

Optionally, an orthogonal projection of each of the plurality of isolation openings 12c on the array substrate 11 includes at least one projection edge S1 parallel to the second direction Y. As mentioned above, the deposition material is more easily deposited onto a part of the side walls (the side wall parallel to the second direction Y) of the isolation layer 12, thereby enabling a better connection performance between the second electrode 133 and the isolation layer 12.

In one embodiment, in the same isolation opening 12c, areas of orthogonal projections of the plurality of sub-isolation openings 12c1 on the array substrate 11 are the same. Here, the “orthogonal projection of a sub-isolation opening 12c1 on the array substrate 11” refers to an orthogonal projection of side walls with the narrowest aperture of the sub-isolation opening 12c1 on the array substrate 11. Thus, it is beneficial to make the areas of each light-emitting sub-structure 1321 equal, thereby facilitating improving uniformity of light emission. Due to the manufacturing process errors, the equality between A and B as described in the specification not only includes absolute equality but also approximate equality. For example, when A and B satisfy the relationship 0.95B≤A≤1.05B, or, 0.95A≤B≤1.05A, A and B are also considered equal.

Optionally, in the same isolation opening 12c, shapes of the orthogonal projections of the plurality of sub-isolation openings 12c1 on the array substrate 11 are the same. Thus, it is beneficial to ensure that the shapes of all light-emitting sub-structures 1321 remain consistent, not only further improving the uniformity of light emission, but also being beneficial to reduce large-angle viewing bias.

Optionally, in the same isolation opening 12c, orthogonal projections of two adjacent sub-isolation openings 12c1 on the array substrate 11 are arranged symmetrically. Thus, it is beneficial to maintain the axial symmetry of the shape of the emitting light structure 1321, which not only further improves the uniformity of light emission, but also reduced the large-angle viewing bias. Exemplarily, two adjacent sub-isolation openings 12c1 may be arranged symmetrically about a centerline of the partition wall 12b between the two adjacent sub-isolation openings 12c1.

Optionally, in the same isolation opening 12c, orthogonal projections of the two adjacent sub-isolation openings 12c1 on the array substrate 11 are symmetrically centered. Thus, it is beneficial to maintain the centered symmetry of the shape of the emitting light structure 1321, which not only further improves the uniformity of light emission, but also reduces the large-angle viewing bias. Exemplarily, two adjacent sub-isolation openings 12c1 may be arranged symmetrically about a centroid of the partition wall 12b between the two adjacent sub-isolation openings 12c1.

In one embodiment, in the same isolation opening 12c, the areas of orthogonal projections of the plurality of sub-isolation openings 12c1 on the array substrate 11 are not equal. Thus, it is beneficial for designers to carry out special designs for an arrangement of the light-emitting sub-structure 1321 based on actual requirements, thereby enhancing the display effect.

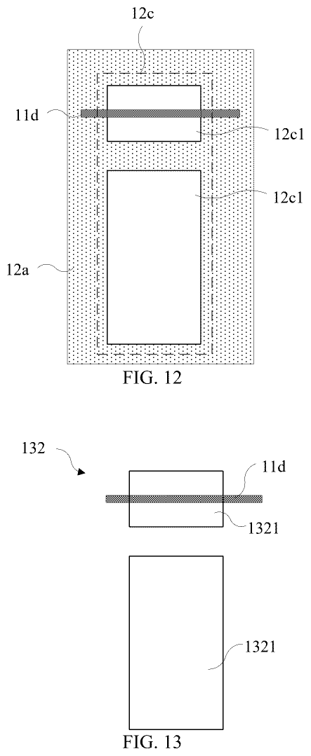

Optionally, as shown in FIG. 12, the array substrate 11 may further include a first wiring line 11d. In at least two sub-isolation openings 12c1 of the same isolation opening 12c, an orthogonal projection of at least one sub-isolation opening 12c1 on the array substrate 11 overlaps with an orthogonal projection of the first wiring line 11d on the array substrate 11, and the orthogonal projection of at least one sub-isolation opening 12c1 on the array substrate 11 does not overlap with the orthogonal projection of the first wiring line 11d on the array substrate 11. As shown in FIG. 13, in light-emitting sub-structures 1321 corresponding to the two sub-isolation openings 12c1, one light-emitting sub-structure 1321 overlaps with the first wiring line 11d while the other light-emitting sub-structure 1321 does not overlap with the first wiring line 11d. Thus, it is equivalent to that a projected area of the sub-isolation opening 12c1 is designed to be different based on an overlapping situation between the sub-isolation opening 12c1 and the first wiring line 11d (whether overlap or not). It is beneficial for the designers to design the area of light-emitting sub-structure 1321 differently based on the overlapping situation between light-emitting sub-structure 1321 and first wiring line 11d. The wiring lines in the array substrate 11 are highly reflective. When the first wiring line 11d is located below the light-emitting sub-structure 1321, it can have a certain impact on the light-emitting effect of the light-emitting sub-structure 1321. Therefore, when the first wiring line 11 d overlaps with the light-emitting structure 132, designers need to carry out some special designs to reduce the impact of the first wiring line 11d on the light emission effect. The above-mentioned differentiated designs are beneficial for reducing the impact of the first wiring line 11d on the light emission effect. Exemplarily, the first wiring line 11d may be a wiring line for transmitting an anode signal, but the type of signal transmitted by the first wiring line 11d is not particularly limited in the embodiments of the present disclosure.

Optionally, as shown in FIG. 12, the orthogonal projection of at least one sub-isolation opening 12c1 on the array substrate 11 overlaps with the orthogonal projection of the first wiring line 11d on the array substrate 11, and an overlapping projection is arranged symmetrically about a centerline of the orthogonal projection of the at least one sub-isolation opening 12c1 on the array substrate 11. As shown in FIG. 13, an orthogonal projection of one light-emitting sub-structure 1321 on the array substrate 11 overlaps with the orthogonal projection of the first wiring line 11d on the array substrate 11, and an overlapping projection is arranged symmetrically about a centerline of an orthogonal projection of the light-emitting sub-structure 1321 on the array substrate 11.

Taking an orientation in FIG. 13 as an example, an overlapping orthogonal projection of an upper light-emitting sub-structure 1321 with the first wiring line 11d is arranged symmetrically about a centerline, along the horizontal direction, of the light-emitting sub-structure 1321. When an observer views the display panel 10 from above and from below at large-angle viewing, display effects observed are almost identical. Thus, this arrangement therefore reduces the large-angle viewing bias.

In one embodiment, as shown in FIG. 7, a minimum distance between two adjacent isolation openings 12c is a first spacing a. In a same isolation opening 12c, a minimum distance between two adjacent sub-isolation openings 12c1 is a second spacing b. The first spacing and the second distance are not equal. Thus, it is beneficial for the designers to adaptively adjust a size of the isolation opening 12c based on actual requirements. For example, when the first spacing a is less than the second spacing b, the light-emitting sub-structure 1321 of the light-emitting structure 132 is arranged more sparsely. This is beneficial for arrangement of the conductive structure 11c for connecting the anode and the driver circuit in a region between adjacent light-emitting sub-structures 1321. Thus, it facilitates the designer to set a position of the conductive structure 11c based on actual requirements, thereby reducing restrictions on the setting position of a through-hole structure caused by the arrangement position of the light-emitting structure 132. When the first spacing a is greater than the second spacing b, the light-emitting sub-structure 1321 of the light-emitting structure 132 is arranged more compactly. This is beneficial for maximizing the aperture ratio and minimizing the loss of the separated light-emitting structure 132 on the aperture ratio.

Optionally, the second spacing b is less than the first spacing a. That is, the first spacing a is greater than the second spacing b. Thus, the light-emitting sub-structure 1321 of the light-emitting structure 132 is arranged more compactly, and an light-emitting area of the light-emitting sub-structure 1321 is set to be larger. This is beneficial for maximizing the aperture ratio and minimizing the loss of the separated light-emitting structure 132 on the aperture ratio, thereby ensuring the display effect.

Optionally, a difference between the first spacing a and the second spacing b is greater than 0 μm and less than or equal to 16 μm. Exemplarily, the difference between the first spacing a and the second spacing b may be 0.1 μm, 1 μm, 3 μm, 5 μm, 8 μm, 12 μm, 14 μm, 16 μm, or any value within the range of the above-mentioned numeral values. By making the difference between the first spacing a and the second spacing b fall within the above-mentioned range, it is beneficial for improving the aperture ratio and ensuring the display effect.

In one embodiment, the second electrodes 133 of at least part of the plurality of light-emitting devices 13 are electrically connected to the isolation layer 12. The isolation layer 12 may be electrically connected to the driver circuit of the display panel 10. In the embodiments of the present disclosure, the isolation layer 12 is configured to connect the second electrode 133 of the light-emitting device 13 to the driver circuit, thereby allowing a more optimized wiring line layout in the display region of the display panel 10.

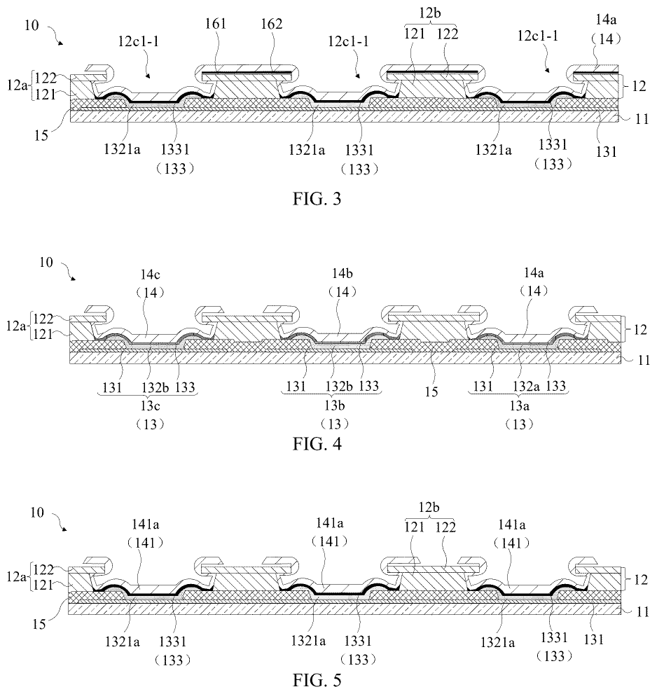

Optionally, as shown in FIGS. 3 to 5, both the isolation structure 12a and the partition wall 12b include a conductive portion 121 and a barrier portion 122 stacked in a direction away from the array substrate 11. An orthogonal projection of the conductive portion 121 on the array substrate 11 is located within an orthogonal projection of the barrier portion 122 on the array substrate 11. The second electrode 133 of at least part of the plurality of the light-emitting devices 13 is in contact with the conductive portion 121. Thus, the second electrode 133 may be electrically connected to the isolation layer 12. The “orthogonal projection of the barrier portion 122 of the sub-isolation opening 12c1 on the array substrate 11” refers to: an orthogonal projection of a lower surface (bottom surface) of the barrier portion 122 surrounding the sub-isolation opening 12c1 on the array substrate 11.

In one embodiment, the conductive portion 121 includes at least one metal layer. In one example, the conductive portion 121 includes one metal layer. Furthermore, a material of the conductive portion 121 includes at least one of metal and metal oxide. Exemplarily, the metal may be Ag, Cu, Ti, Al and Mo, etc. The metal oxide may be SnO₂, ZnO, CdO, ¿₂O₃, ITO, IZO, GZO, AZO, Ta—TiO₂, etc.

In one embodiment, a material of barrier portion 122 includes Ti or Mo.

Optionally, the second electrode 133 of at least one light-emitting device 13 includes a plurality of sub-electrode portions 1331 in one-to-one correspondence with the plurality of light-emitting sub-structures 1321, each of the plurality of sub-electrode portions 1331 is in contact with the conductive portion 121. Thus, the sub-electrode portion 1331 corresponding to each light-emitting sub-structure 1321 is electrically connected to the isolation layer 12, preventing impact on the sub-electrode portions 1331 on other light-emitting sub-structures 1321 caused by damage of the sub-electrode portion 1331 of a certain light-emitting sub-structure 1321, thereby enhancing the light emission reliability of the display panel 10.

Optionally, at least part of an outer edge of each sub-electrode portion 1331 covers a side wall, close to the isolation opening 12c, of the conductive portion 121. Thus, a contact area between the sub-electrode portion 1331 and the conductive portion 121 may be larger, thereby reducing electrical bonding resistance.

When a certain second electrode 133 is of an integrated structure and is not separated into the plurality of sub-electrode portions 1331, then at least part of an outer edge of the second electrode 133 covers the side wall of a side, close to the isolation opening 12c, of the conductive portion 121.

Optionally, in the same light-emitting device 13, maximum distances between outer edges of the plurality of sub-electrode portions 1331 and the array substrate 11 are the same. In other words, overlapping heights of all sub-electrode portions 1331 on the isolation layer 12 are the same. Due to the influence of the manufacturing process, “approximately equal” may also be regarded as equal. The above settings are beneficial to ensuring that the electrical bonding resistance between each sub-electrode portion 1331 and the isolation layer 12 remains consistent, thereby improving the uniformity of light emission.

Optionally, an orthogonal projection of the first electrode 131 of at least one light-emitting device 13 on the array substrate 11 covers an orthogonal projection of a surface, closer to the array substrate 11, of the barrier portion 122 of the partition wall 12b corresponding to the at least one light-emitting device 13 on the array substrate 11. That is, the orthogonal projection of the first electrode 131 on the array substrate 11 covers an orthogonal projection of the lower surface (bottom surface) of the barrier portion 122 of the partition wall 12b on the array substrate 11.

In one embodiment, as shown in FIGS. 2 to 5, the display panel 10 may further include a plurality of encapsulation portions 14 in one-to-one correspondence with the plurality of light-emitting devices 13, and each of the plurality of encapsulation portions 14 is arranged on a side, facing away from the array substrate 11, of the corresponding light-emitting device 13. Exemplarily, the encapsulation portion 14 is an inorganic layer.

Optionally, an orthogonal projection of an encapsulation portion 14 corresponding to the at least one light-emitting device 13 on the array substrate 11, covers an orthogonal projection of the partition wall 12b corresponding to the at least one light-emitting device 13 on the array substrate 11 and orthogonal projections of the plurality of light-emitting sub-structures 1321 corresponding to the at least one light-emitting device 13 on the array substrate 11. That is, the encapsulation portion 14 is a continuous layer structure. Thus, a contact area between the encapsulation portion 14 and the other layers in the display panel 10 may be increased, thereby enhancing connection stability of the encapsulation portion 14, and improving the encapsulation reliability.

Optionally, a light-emitting material layer 161 and an electrode material layer 162 stacked in sequence are further provided between the partition wall 12b and the plurality of encapsulation portions 14.

Optionally, as shown in FIG. 5, the encapsulation portion 14 corresponding to at least one light-emitting device 13 includes a plurality of sub-encapsulation portions 141 spaced apart in one-to-one correspondence with the plurality of light-emitting sub-structures 1321. A sub-encapsulation portion 141 is disposed on a side, facing away from the array substrate 11, of the corresponding light-emitting sub-structure 1321. Thus, each light-emitting sub-structure 1321 is separately encapsulated. In this way, when the encapsulation portion of a certain sub-encapsulation portion 141 fails, it will not affect the encapsulation performance of other sub-encapsulation portions 141, allowing other light-emitting sub-structures 1321 to still emit light normally, thereby reducing the risk of display defects in the display panel 10.

In one embodiment, as shown in FIGS. 3, 4, and 10, the display panel 10 may further include a pixel defining layer 15 arranged between the array substrate 11 and the isolation layer 12 and defining a plurality of pixel openings 15a in one-to-one correspondence with the plurality of light-emitting devices 13. At least part of the light-emitting device 13 is arranged in the corresponding pixel opening 15a.

Optionally, the pixel opening 15a corresponding to at least one light-emitting device 13 includes a plurality of sub-pixel openings 15a1 in one-to-one correspondence with the plurality of light-emitting sub-structures 1321. The plurality of sub-pixel openings 15a1 of the pixel opening 15a are in communication with the plurality of sub-isolation openings 12c1 of the isolation opening 12c corresponding to the pixel opening 15a in one-to-one correspondence.

Optionally, a distance between two adjacent pixel openings 15a is a third spacing c. In the same pixel opening 15 a, a distance between two adjacent sub-pixel openings 15a1 is a fourth spacing d. The third spacing c and the fourth spacing d are not equal. Thus, it is beneficial for the designers to adaptively adjust a size of the pixel opening 15a based on actual requirements. For example, when the third spacing c is less than the fourth spacing d, the light-emitting sub-structure 1321 of the light-emitting structure 132 is arranged more sparsely. This is beneficial for setting the conductive structure 11c for connecting the anode and the driver circuit in a region between adjacent light-emitting sub-structures 1321. Thus, it facilitates the designer to set a position of the conductive structure 11c based on actual requirements, thereby reducing restrictions on the setting position of the conductive structure 11c caused by the arrangement position of the light-emitting structure 132. When the third spacing c is greater than the fourth spacing d, the light-emitting sub-structure 1321 of the light-emitting structure 132 is arranged more compactly. This is beneficial for maximizing the aperture ratio and minimizing the loss of the separated light-emitting structure 132 on the aperture ratio.

Optionally, as shown in FIG. 11, a maximum distance between an outer contour of the orthogonal projection of the sub-isolation opening 12c1 on the array substrate 11 and an outer contour of the orthogonal projection of the corresponding sub-pixel opening 15a1 on the array substrate 11 is a first distance e. Here, the “outer contour of the orthogonal projection of the sub-isolation opening 12c1 on the array substrate 11” refers to a contour of an orthogonal projection of side walls with the narrowest aperture of the sub-isolation opening 12c1 on the array substrate 11. The “outer contour of the orthogonal projection of the corresponding sub-pixel opening 15a1 on the array substrate 11” refers to a contour of an orthogonal projection of an edge of a side, closer to the array substrate 11, of the sub-pixel opening 15a1 on the array substrate 11.

Specifically, in the same isolation opening 12c, the first distances e corresponding to at least two sub-isolation openings 12c1 are the same. Thus, it is beneficial for at least two sub-isolation openings 12c in the same isolation opening 12c to align precisely with the corresponding sub-pixel openings 15a1 in the same pixel opening 15a, thereby enhancing the display uniformity in the large-angle viewing bias.

Optionally, in the same isolation opening 12c, the first distances e corresponding to all sub-isolation openings 12c1 are the same. Thus, it is beneficial for each sub-isolation opening 12c in the same isolation opening 12c to align precisely with the corresponding sub-pixel opening 15a1 in the same pixel opening 15 a, thereby enhancing the display uniformity in the large-angle viewing bias.

In one embodiment, as shown in FIG. 14, an inner wall of the isolation opening 12c includes a first straight side S2 parallel to a plane located by the array substrate 11. The plurality of first isolation openings 12c-1 are arranged along a first direction X to form a plurality of first isolation opening rows 12f, the plurality of second isolation openings 12c-2 and the plurality of third isolation openings 12c-3 are alternately arranged along the first direction X to form a plurality of second isolation opening rows 12g, and the plurality of first isolation-opening rows 12 f and the plurality of second isolation-opening rows 12g are alternately arranged along a second direction Y intersecting the first direction X. Adjacent second isolation opening 12c-2 and third isolation opening 12c-3 are located in a first virtual quadrilateral N1. The first straight side S2 of at least one of the second isolation opening 12c-2 and the third isolation opening 12c-3 is located on an edge of the first virtual quadrilateral N1, and at least one first isolation opening 12c-1 is located in the first virtual quadrilateral N1. Exemplarily, the first direction X is perpendicular to the second direction Y. The above setting enables the first light-emitting device 13a, the second light-emitting device 13b, and the third light-emitting device 13c to be arranged in a specific manner, and is beneficial for enhancing the display effect of the display panel 10. Due to the manufacturing process errors, the perpendicularity between A and B as described in the specification not only includes absolute perpendicularity but also approximate perpendicularity. For example, when an angle between A and B is ranges from 85° to 95°, it is also considered that A is perpendicular to B.

In an example, the first straight side S2 is located on a surface of a side, close to the isolation opening 12c, of the conductive portion 121. In another example, the first straight side S2 is located on a surface, of a side, close to the isolation opening 12c, of the barrier portion 122.

Optionally, both the first straight sides S2 of the second isolation opening 12c-2 and the third isolation opening 12c-3 are located on edges of the first virtual quadrilateral N1.

Optionally, the first straight side S2 is located on a surface, of a side, close to the isolation opening 12c, of the conductive portion 121, a part of an edge of the second electrode 133 of each light-emitting device 13 is arranged on the first straight side S2. Thus, it is beneficial to improve the connection performance between the second electrode 133 and the conductive portion 121, thereby facilitating reduction of the bonding resistance.

Optionally, the second isolation opening 12c-2 is located at a first vertex N2-1 of the second virtual quadrilateral N2, the third isolation opening 12c-3 is located at a second vertex N2-2 of the second virtual quadrilateral N2. The first vertex N2-1 and the second vertex N2-2 are alternated and spaced apart. Furthermore, the first isolation opening 12c-1 is located in the second virtual quadrilateral N2, and a center of the first isolation opening 12c-1 (i.e., the centroid of the first isolation opening 12c-1) is offset from a center of the second virtual quadrilateral N2. When the first isolation opening 12 c-1 includes a plurality of first sub-isolation openings 12c1-1, then the centroid of the first isolation opening 12c-1 is the centroid of a shape formed by outer edges of the plurality of first isolation openings 12c-1 together.

Optionally, along the first direction X, the second virtual quadrilateral N2 includes a first side N2-3 and a second side N2-4 opposite, and a length of the first side N2-3 is less than a length of the second side N2-4. Furthermore, the second virtual quadrilateral N2 may further include a third side N2-5 and a fourth side N2-6 opposite along the second direction Y. Optionally, the first side N2-3 is parallel with the second side N2-4. Optionally, the second virtual quadrilateral N2 is a trapezoid.

Optionally, as shown in FIGS. 14, 15, and 16, the first isolation opening 12c-1 includes two first sub-isolation openings 12c1-1, and the first light-emitting structure 132 a includes two first light-emitting sub-structures 1321a. The second light-emitting structure 132b and the third light-emitting structure 132c are not separated.

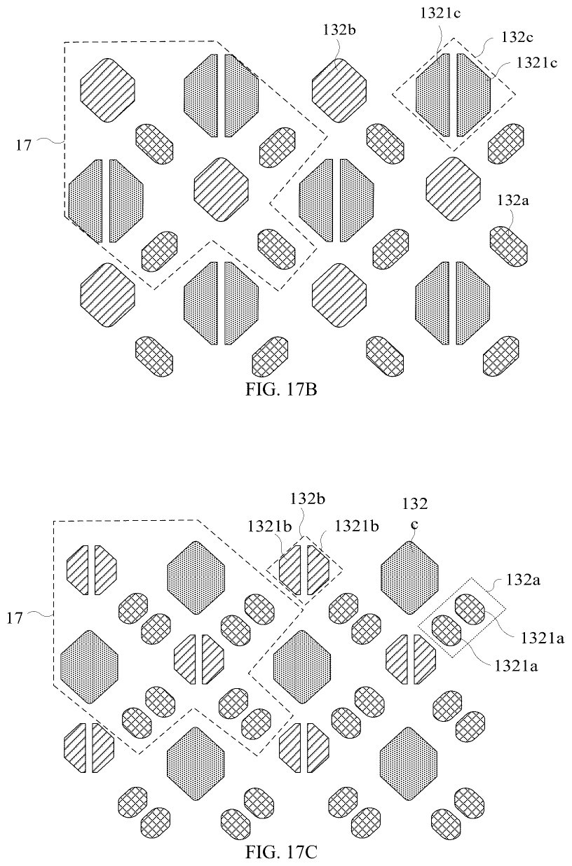

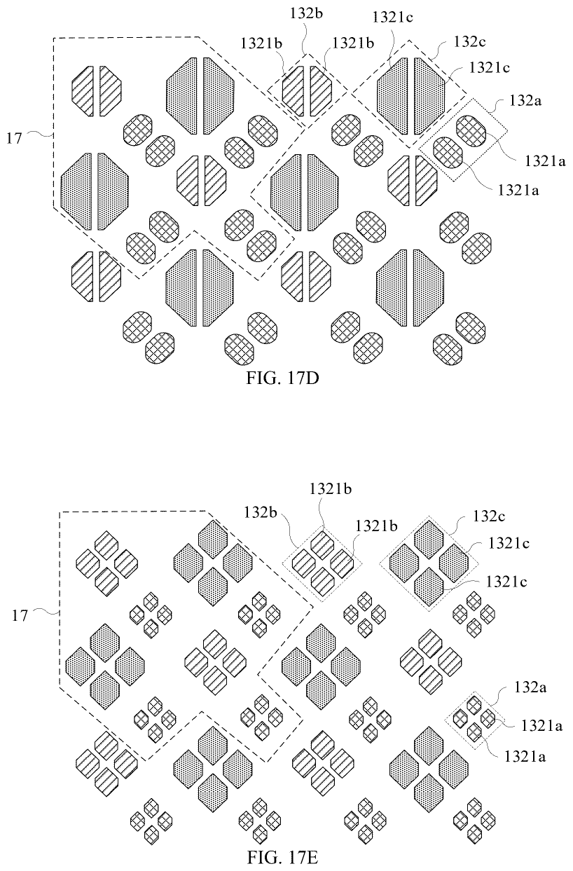

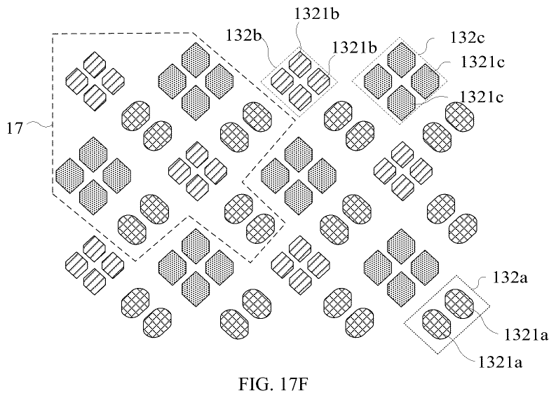

Optionally, as shown in FIG. 17A, the second light-emitting structure 132b includes two second light-emitting sub-structures 1321b. The first light-emitting structure 132a and the third light-emitting structure 132c are not separated. Optionally, as shown in FIG. 17B, the third light-emitting structure 132c includes two third light-emitting sub-structures 1321c. The first light-emitting structure 132a and the second light-emitting structure 132b are not separated. Optionally, as shown in FIG. 17C, the first light-emitting structure 132a includes two first light-emitting sub-structures 1321a, the second light-emitting structure 132b includes two second light-emitting sub-structures 1321b, and the third light-emitting structure 132c is not separated. Optionally, as shown in FIG. 17D, the first light-emitting structure 132a includes two first light-emitting sub-structures 1321a, the second light-emitting structure 132b includes two second light-emitting sub-structures 1321b, and the third light-emitting structure 132c includes two third light-emitting sub-structures 1321c. Optionally, as shown in FIG. 17E, the first light-emitting structure 132a includes four first light-emitting sub-structures 1321a, the second light-emitting structure 132b includes four second light-emitting sub-structures 1321b, and the third light-emitting structure 132c includes four third light-emitting sub-structures 1321c. Optionally, as shown in FIG. 17E, the first light-emitting structure 132a includes two first light-emitting sub-structures 1321a, the second light-emitting structure 132b includes four second light-emitting sub-structures 1321b, and the third light-emitting structure 132c includes four third light-emitting sub-structures 1321c. In the arrangement shown in FIGS. 17A to 17F, four first light-emitting structures 132a, two second light-emitting structures 132b, and two third light-emitting structures 132c form one light-emitting unit group 17 together, and a plurality of light-emitting unit groups 17 are arranged in an array.

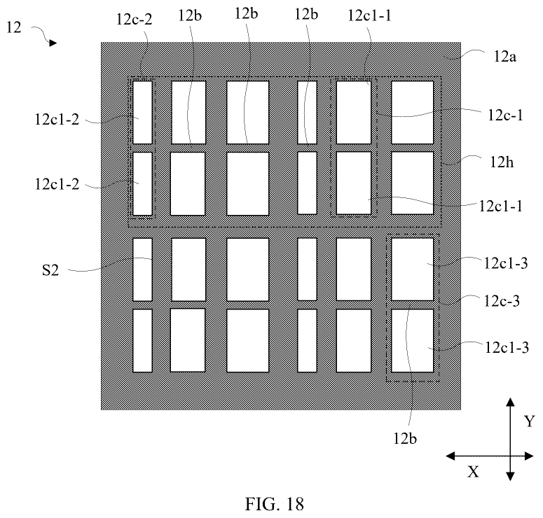

In one embodiment, as shown in FIG. 18, the plurality of first isolation openings 12c-1, the plurality of second isolation openings 12c-2, and the plurality of third isolation openings 12c-3 are arranged along the first direction X to form a plurality of third isolation-opening rows 12h, the plurality of third isolation-opening rows 12h are sequentially arranged along the second direction Y intersecting the first direction X. In the same third isolation-opening row 12h, the first isolation opening 12c-1, the second isolation opening 12c-2, and the third isolation opening 12c-3 are alternately arranged in sequence. Exemplarily, the first direction X is perpendicular to the second direction Y. The above settings enable the display panel 10 to achieve a better display effect.

Optionally, the array substrate 11 includes a plurality of scan lines 11b spaced apart along the second direction Y, and each scan line 11b extends along the first direction X. An inner wall of the plurality of isolation openings 12c includes a first straight side S2 parallel to the second direction Y. Thus, during the deposition of the second electrode 133, the deposition source is used to scan along the first direction X, so that the deposition material is more easily deposited onto the first straight side S2, thereby enabling a better connection performance between the second electrode 133 and the isolation layer 12.

Optionally, a length of the first isolation opening 12c-1 along the second direction Y, a length of the second isolation opening 12c-2 along the second direction Y, and a length of the third isolation opening 12c-3 along the second direction are the same. Thus, lengths of the first light-emitting structure 132a, the second light-emitting structure 132b, and the third light-emitting structure 132c may remain consistent, thereby maximizing the aperture ratio.

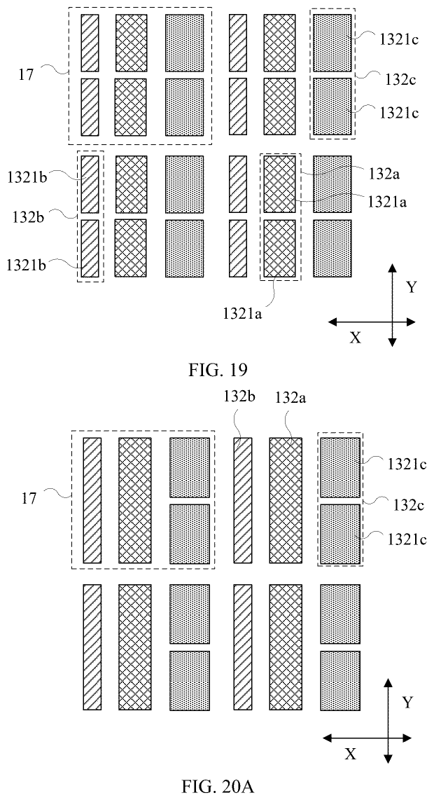

Optionally, as shown in FIGS. 18 and 19, the first isolation opening 12c-1 includes two first sub-isolation openings 12c1-1 arranged along the second direction Y, the second isolation opening 12c-2 includes two second sub-isolation openings 12c1-2 arranged along the second direction Y, and the third isolation opening 12c-3 includes two third sub-isolation openings 12c1-3 arranged along the second direction Y. The first light-emitting structure 132a includes two first light-emitting sub-structures 1321a, the second light-emitting structure 132b includes two second light-emitting sub-structures 1321b, and the third light-emitting structure 132c includes two third light-emitting sub-structures 1321c.

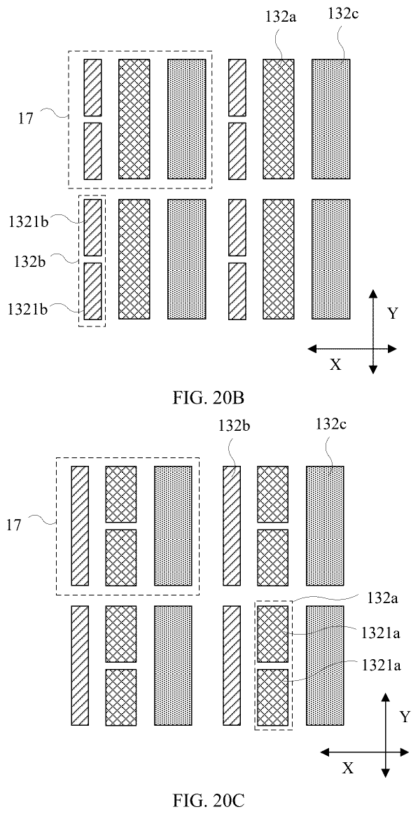

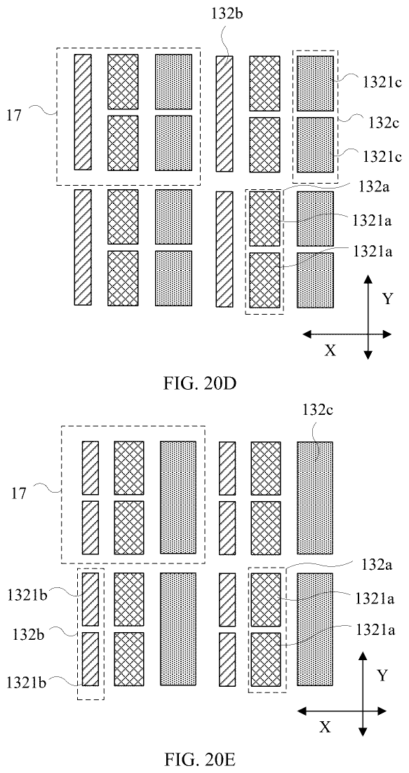

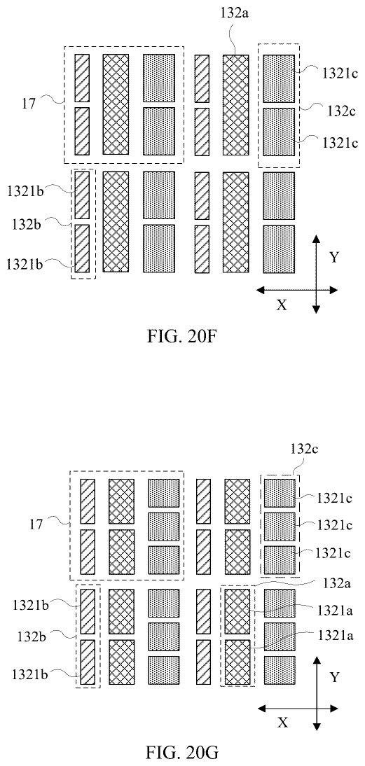

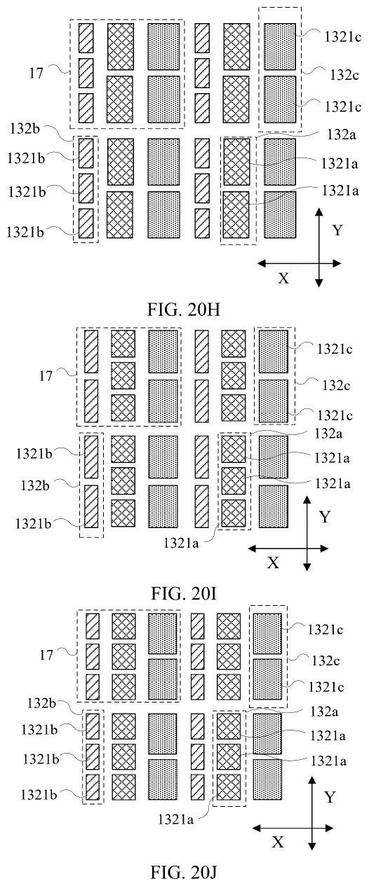

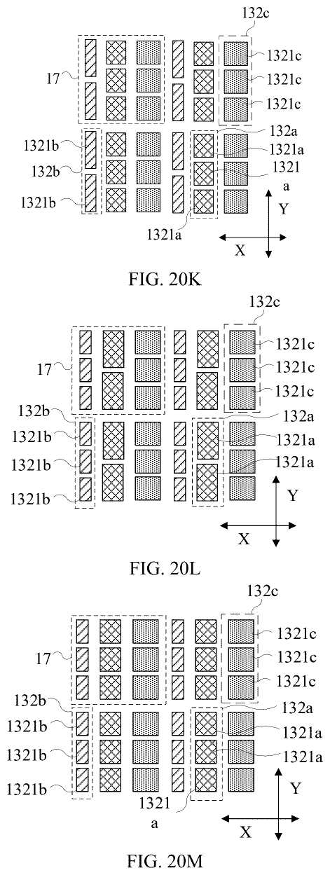

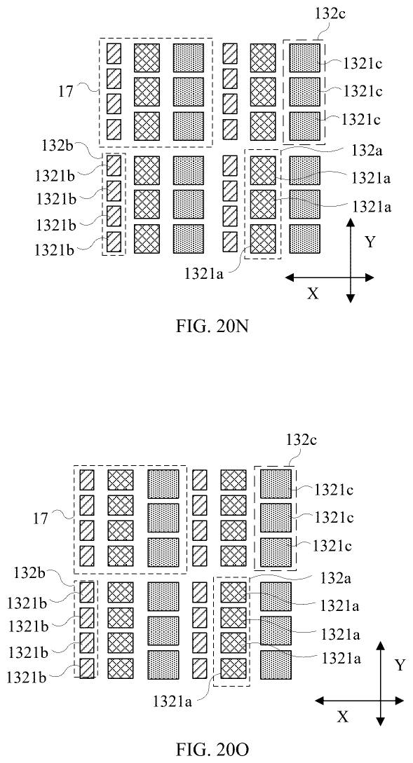

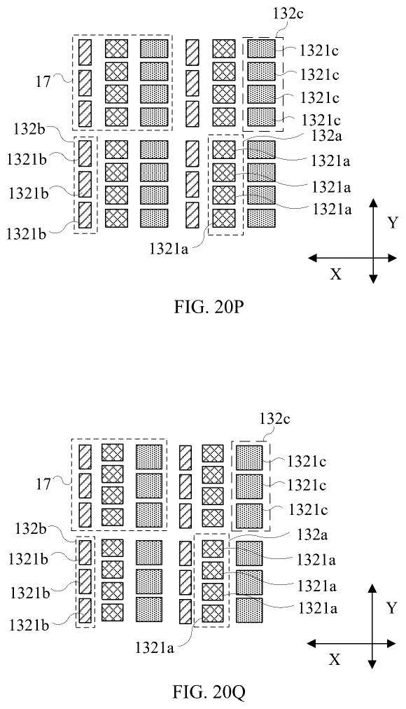

Optionally, as shown in FIG. 20A, the third light-emitting structure 132c includes two third light-emitting sub-structures 1321c. The first light-emitting structure 132a and the second light-emitting structure 132b are not separated. Optionally, as shown in FIG. 20B, the second light-emitting structure 132b includes two second light-emitting sub-structures 1321b. The first light-emitting structure 132a and the third light-emitting structure 132c are not separated. Optionally, as shown in FIG. 20C, the first light-emitting structure 132a includes two first light-emitting sub-structures 1321a. The second light-emitting structure 132b and the third light-emitting structure 132c are not separated. Optionally, as shown in FIG. 20D, the first light-emitting structure 132a includes two first light-emitting sub-structures 1321a, the third light-emitting structure 132c includes two third light-emitting sub-structures 1321c. The second light-emitting structure 132b is not separated. Optionally, as shown in FIG. 20E, the first light-emitting structure 132a includes two first light-emitting sub-structures 1321a, the second light-emitting structure 132b includes two second light-emitting sub-structures 1321b. The third light-emitting structure 132c is not separated. Optionally, as shown in FIG. 20F, the second light-emitting structure 132b includes two second light-emitting sub-structures 1321b, the third light-emitting structure 132c includes two third light-emitting sub-structures 1321c. The first light-emitting structure 132a is not separated. Optionally, as shown in FIG. 20G, the first light-emitting structure 132a includes two first light-emitting sub-structures 1321a, the second light-emitting structure 132b includes two second light-emitting sub-structures 1321b, the third light-emitting structure 132c includes three of the third light-emitting sub-structures 1321c. Optionally, as shown in FIG. 20H, the first light-emitting structure 132a includes two first light-emitting sub-structures 1321a, the second light-emitting structure 132b includes three of the second light-emitting sub-structures 1321b, the third light-emitting structure 132c includes two third light-emitting sub-structures 1321c. Optionally, as shown in FIG. 20I, the first light-emitting structure 132 a includes three of the first light-emitting sub-structures 1321a, the second light-emitting structure 132b includes two second light-emitting sub-structures 1321b, the third light-emitting structure 132c includes two third light-emitting sub-structures 1321c. Optionally, as shown in FIG. 20J, the first light-emitting structure 132a includes three of the first light-emitting sub-structures 1321a, the second light-emitting structure 132b includes three of the second light-emitting sub-structures 1321b, the third light-emitting structure 132c includes two third light-emitting sub-structures 1321c. Optionally, as shown in FIG. 20K, the first light-emitting structure 132a includes three of the first light-emitting sub-structures 1321a, the second light-emitting structure 132b includes two second light-emitting sub-structures 1321b, the third light-emitting structure 132c includes three of the third light-emitting sub-structures 1321c. Optionally, as shown in FIG. 20L, the first light-emitting structure 132a includes two first light-emitting sub-structures 1321a, the second light-emitting structure 132b includes three of the second light-emitting sub-structures 1321b, the third light-emitting structure 132c includes three of the third light-emitting sub-structures 1321c. Optionally, as shown in FIG. 20M, the first light-emitting structure 132a includes three of the first light-emitting sub-structures 1321a, the second light-emitting structure 132b includes three of the second light-emitting sub-structures 1321b, the third light-emitting structure 132c includes three of the third light-emitting sub-structures 1321c. Optionally, as shown in FIG. 20N, the first light-emitting structure 132a includes three of the first light-emitting sub-structures 1321a, the second light-emitting structure 132b includes four second light-emitting sub-structures 1321b, the third light-emitting structure 132c includes three of the third light-emitting sub-structures 1321c. Optionally, as shown in FIG. 20O, the first light-emitting structure 132a includes four first light-emitting sub-structures 1321a, the second light-emitting structure 132b includes four second light-emitting sub-structures 1321b, the third light-emitting structure 132c includes three of the third light-emitting sub-structures 1321c. Optionally, as shown in FIG. 20P, the first light-emitting structure 132a includes four first light-emitting sub-structures 1321a, the second light-emitting structure 132b includes three of the second light-emitting sub-structures 1321b, the third light-emitting structure 132c includes four third light-emitting sub-structures 1321c. Optionally, as shown in FIG. 20Q, the first light-emitting structure 132a includes four first light-emitting sub-structures 1321a, the second light-emitting structure 132b includes three of the second light-emitting sub-structures 1321b, the third light-emitting structure 132c includes three of the third light-emitting sub-structures 1321c. In the arrangement shown in FIGS. 20A to 20Q, a first light-emitting structure 132a, a second light-emitting structure 132b, and a third light-emitting structure 132c form a light-emitting unit group 17 together, and the plurality of light-emitting unit groups 17 are arranged in an array.

The greater the quantity of the light-emitting sub-structures 1321 in the light-emitting structure 132 is, the smaller the area proportion of a single light-emitting sub-structure 1321 is. When a certain light-emitting sub-structure 1321 fails, it has a relatively smaller impact on the overall light-emitting effect of the light-emitting structure 132.

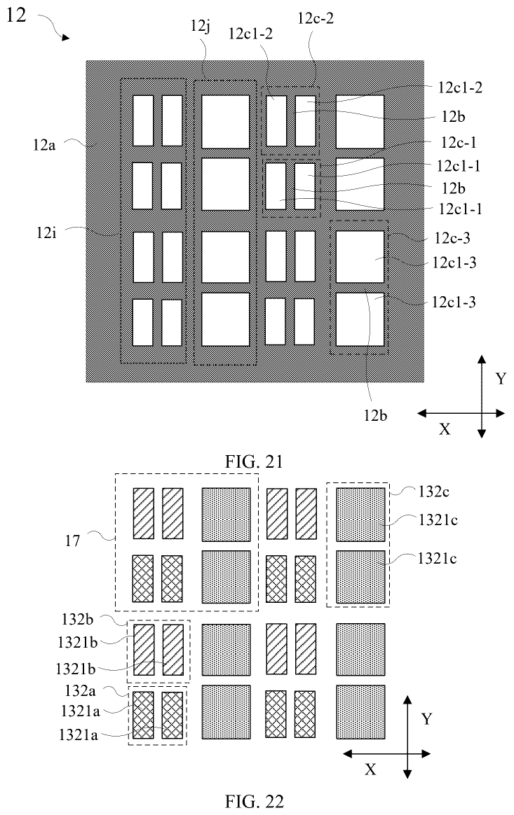

In one embodiment, as shown in FIG. 21, the plurality of first isolation openings 12c-1 and the plurality of second isolation openings 12c-2 are alternately arranged along a second direction Y to form a plurality of first isolation opening columns 12i, the plurality of third isolation openings 12c-3 are arranged along the second direction Y to form a plurality of second isolation opening columns 12j, the plurality of first isolation opening columns 12i and the plurality of second isolation opening columns 12j are alternately arranged along a first direction X intersecting the second direction Y. Exemplarily, the first direction X is perpendicular to the second direction Y. Thus, the display panel 10 may achieve a better display effect.

Optionally, as shown in FIG. 21, the first isolation opening 12c-1 includes a plurality of first sub-isolation openings 12c1-1 arranged along the first direction X, and a partition wall 12b is arranged between two adjacent first sub-isolation openings 12c1-1. The second isolation openings 12c-2 includes a plurality of second sub-isolation openings 12c1-2 arranged along the first direction X, and the partition wall 12b is arranged between two adjacent second sub-isolation openings 12c1-2. The third isolation openings 12 c-3 includes the plurality of third sub-isolation openings 12c1-3 arranged along the first direction X, and the partition wall is arranged between two adjacent third sub-isolation openings 12c1-3. Thus, a length of the first sub-isolation opening 12c1-1 along the second direction Y may be made greater than a length along the first direction X; a length of the second sub-isolation opening 12c1-2 along the second direction Y may be made greater than a length along the first direction X; and a length of the third sub-isolation opening 12c1-3 along the second direction Y may be made greater than a length along the first direction X. In other words, longer sides of the first sub-isolation opening 12c1-1, the second sub-isolation opening 12c1-2, and the third sub-isolation opening 12c1-3 extend along the second direction Y. Thus, during the deposition of the second electrode 133, the deposition source is used to scan along the first direction X, so that he deposition material is more easily deposited onto the long edges of each sub-isolation opening 12c1, thereby enabling a better connection performance between the second electrode 133 and the isolation layer 12.

Optionally, an extending direction (length direction) of the partition wall 12b between two adjacent first sub-isolation openings 12c1-1 intersects an extending direction (length direction) of the partition wall 12b between two adjacent third sub-isolation openings 12c1-3. Furthermore, the extending direction of the partition wall 12b between two adjacent first sub-isolation openings 12c1-1 is perpendicular to the extending direction of the partition wall 12 b between two adjacent third sub-isolation openings 12c1-3.

Optionally, an extending direction (length direction) of the partition wall 12b between two adjacent second sub-isolation openings 12c-2 intersects the extending direction (length direction) of the partition wall 12b between two adjacent third sub-isolation openings 12c1-3. Furthermore, the extending direction of the partition wall 12b between two adjacent second sub-isolation openings 12c-2 is perpendicular to the extending direction of the partition wall 12b between two adjacent third sub-isolation openings 12c1-3.

Optionally, the first isolation opening 12c-1 includes two first sub-isolation openings 12c1-1, the second isolation opening 12c-2 includes two second sub-isolation openings 12c1-2, and the third isolation openings 12c-3 includes two third sub-isolation openings 12c1-3. As shown in FIG. 22, the first light-emitting structure 132a includes two first light-emitting sub-structures 1321a, the second light-emitting structure 132b includes two second light-emitting sub-structures 1321b, the third light-emitting structure 132c includes two third light-emitting sub-structures 1321c. Quantities of the first sub-isolation opening 12c1-1, the second sub-isolation opening 12c1-2, and the third sub-isolation opening 12c1-3 may further be other numeral values. The embodiments of the present disclosure impose no specific limitation on this.

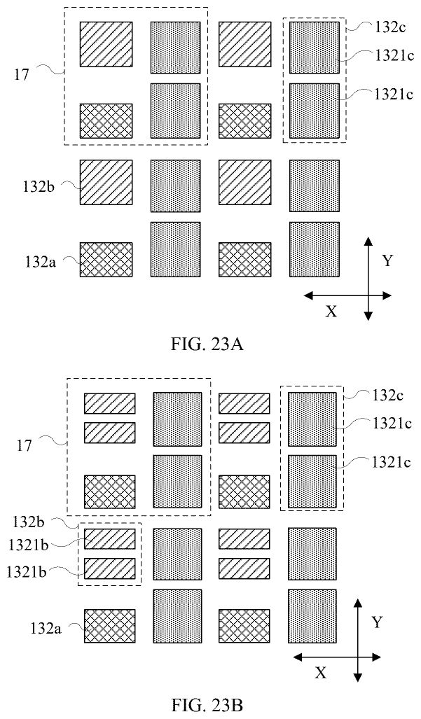

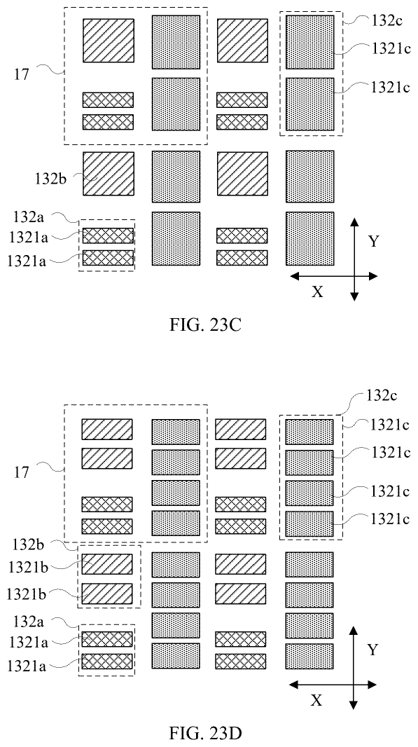

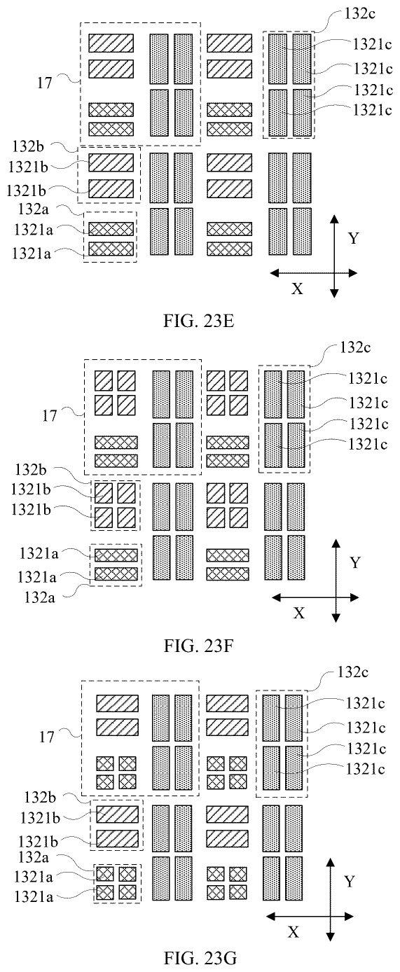

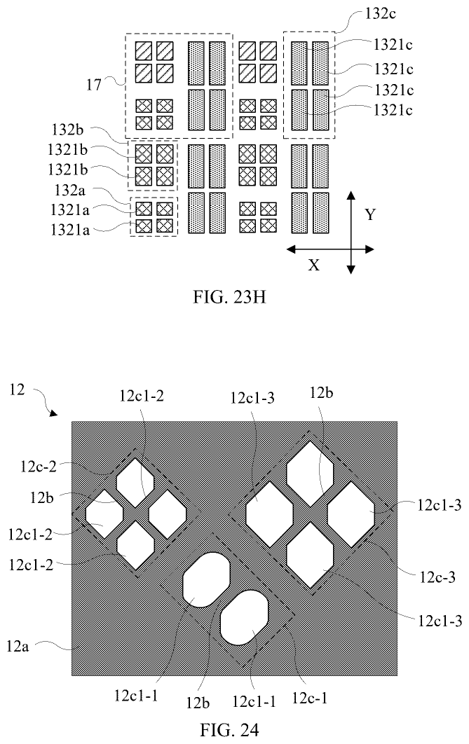

Optionally, as shown in FIG. 23A, the third light-emitting structure 132c includes two third light-emitting sub-structures 1321c arranged along the second direction Y. The first light-emitting structure 132a and the second light-emitting structure 132b are not separated. Optionally, as shown in FIG. 23B, the second light-emitting structure 132b includes two second light-emitting sub-structures 1321b arranged along the second direction Y, the third light-emitting structure 132c includes two third light-emitting sub-structures 1321c arranged along the second direction Y. The first light-emitting structure 132a is not separated. Optionally, as shown in FIG. 23C, the first light-emitting structure 132a includes two first light-emitting sub-structures 1321a arranged along the second direction Y, the third light-emitting structure 132c includes two third light-emitting sub-structures 1321c arranged along the second direction Y. The second light-emitting structure 132b is not separated. Optionally, as shown in FIG. 23D, the first light-emitting structure 132a includes two first light-emitting sub-structures 1321a arranged along the second direction Y, the second light-emitting structure 132b includes two second light-emitting sub-structures 1321b arranged along the second direction Y, the third light-emitting structure 132c includes four third light-emitting sub-structures 1321c arranged along the second direction Y. Optionally, as shown in FIG. 23D, the first light-emitting structure 132a includes two first light-emitting sub-structures 1321a arranged along the second direction Y, the second light-emitting structure 132b includes two second light-emitting sub-structures 1321b arranged along the second direction Y, the third light-emitting structure 132c includes four third light-emitting sub-structures 1321c arranged in two rows along the first direction X, with each row including two third light-emitting sub-structures 1321c. Optionally, as shown in FIG. 23F, the first light-emitting structure 132a includes two first light-emitting sub-structures 1321a arranged along the second direction Y, the second light-emitting structure 132b includes four second light-emitting sub-structures 1321b arranged in two rows along the first direction X, with each row including two second light-emitting sub-structures 1321b, the third light-emitting structure 132c includes four third light-emitting sub-structures 1321c arranged in two rows along the first direction X, with each row including two third light-emitting sub-structures 1321c. Optionally, as shown in FIG. 23G, the first light-emitting structure 132a includes four first light-emitting sub-structures 1321a arranged in two rows along the first direction X, with each row including two first light-emitting sub-structures 1321a, the second light-emitting structure 132b includes two second light-emitting sub-structures 1321b arranged along the second direction Y, the third light-emitting structure 132c includes four third light-emitting sub-structures 1321c arranged in two rows along the first direction X, with each row including two third light-emitting sub-structures 1321c. Optionally, as shown in FIG. 23H, the first light-emitting structure 132a includes four first light-emitting sub-structures 1321a arranged in two rows along the first direction X, with each row including two first light-emitting sub-structures 1321a, he second light-emitting structure 132b includes four second light-emitting sub-structures 1321b arranged in two rows along the first direction X, with each row including two second light-emitting sub-structures 1321b, the third light-emitting structure 132c includes four third light-emitting sub-structures 1321c arranged in two rows along the first direction X, with each row including two third light-emitting sub-structures 1321c. In the arrangement shown in FIGS. 23A to 23Q, a first light-emitting structure 132a, a second light-emitting structure 132b, and a third light-emitting structure 132c form a light-emitting unit group 17 together, and the plurality of light-emitting unit groups 17 are arranged in an array.

In one embodiment, a wavelength of light emitted by the plurality of first light-emitting devices ranges from 505 nm to 45 nm, that is, the first light-emitting device 13a is a green light-emitting device 13. A wavelength of light emitted by the plurality of second light-emitting devices ranges from 600 nm to 50 nm, that is, the second light-emitting device 13b is a red light-emitting device 13. A wavelength of light emitted by the plurality of third light-emitting devices ranges from 440 nm to 480 nm, that is, the third light-emitting device 13c is a blue light-emitting device 13.

Specifically, the light-emitting structure 132 (the second light-emitting structure 132b) of the second light-emitting device 13b includes a plurality of light-emitting sub-structures 1321 (the second light-emitting sub-structure 1321b), and the second isolation opening 12c-2 includes a plurality of second sub-isolation openings 12c1-2. That is, the red light-emitting structure 132 is separated into a plurality of light-emitting sub-structures 1321.

Inventor discovered through research that due to the influence of the manufacturing process sequence, the red light-emitting device 13 is prone to dark spot failure. By separating the red light-emitting structure 132 into the plurality of light-emitting sub-structures 1321, when a certain light-emitting sub-structure 1321 experiences dark spot failure, it will not affect other light-emitting sub-structures 1321, thereby effectively improving the issue of dark spot failure.

Optionally, a shape of an orthogonal projection of the second sub-isolation opening 12c1-2 on the array substrate 11 is a polygon. Here, the polygon may be a quadrilateral, a pentagon, a hexagon, a heptagon, an octagon, a nonagon, etc.

Optionally, as shown in FIG. 17A, the light-emitting structure 132 (the second light-emitting structure 132b) of the second light-emitting device 13b includes two light-emitting sub-structures 1321 (the second light-emitting sub-structure 1321b), and the second isolation opening 12c-2 includes two second sub-isolation openings 12c1-2.

Optionally, as shown in FIG. 17E, the light-emitting structure 132 (the second light-emitting structure 132b) of the second light-emitting devices 13b includes four light-emitting sub-structures 1321 (the second light-emitting sub-structure 1321b), and the second isolation opening 12c-2 includes four second sub-isolation openings 12c1-2. Thus, the quantity of the second light-emitting sub-structures 1321b may be increased. When one of the second light-emitting sub-structures 1321b fails, the remaining second light-emitting sub-structures 1321b may have a larger light-light-emitting area and a better display effect.

Optionally, centroids of the orthogonal projections of four second sub-isolation openings 12c1-2 on the array substrate 11, when connected, define a quadrilateral. That is, the centroids of the orthogonal projections of four second light-emitting sub-structures 1321b on the array substrate 11, when connected, define a quadrilateral. Exemplarily, the quadrilateral may be a trapezoid, a rectangle, a rhombus, a square, etc. Optionally, centroids of the orthogonal projections of four second sub-isolation openings 12c1-2 on the array substrate 11, when connected, define a regular quadrilateral. That is, the centroids of the orthogonal projections of four second light-emitting sub-structures 1321b on the array substrate 11, when connected, define a regular quadrilateral. Thus, an arrangement of the second light-emitting sub-structure 1321b may be made more regular. When one of the second light-emitting sub-structures 1321b fails, the other three second light-emitting sub-structures 1321b may still emit light normally, and a display effect of the other three second light-emitting sub-structures 1321b is not significantly different from a display effect of the four second light-emitting sub-structures 1321b in normal conditions.

In one embodiment, the light-emitting structure 132 of the first light-emitting device 13a includes the plurality of light-emitting sub-structures 1321, and the first isolation opening 12c-1 includes a plurality of first sub-isolation openings 12c1-1. That is, the green light-emitting structure 132 is separated into a plurality of light-emitting sub-structures 1321.

Inventor discovered through research that due to the influence of the manufacturing process sequence, the green light-emitting device 13 is prone to dark spot failure. By separating the green light-emitting structure 132 into the plurality of light-emitting sub-structures 1321, when a certain light-emitting sub-structure 1321 experiences dark spot failure, it will not affect other light-emitting sub-structures 1321, thereby effectively improving the problem of dark spot failure.

Optionally, a shape of an orthogonal projection of the first sub-isolation opening 12c1-1 on the array substrate 11 is a polygon. Here, the polygon can be a quadrilateral, a pentagon, a hexagon, a heptagon, an octagon, a nonagon, etc.

Optionally, as shown in FIG. 17C, the light-emitting structure 132 (the first light-emitting structure 132a) of the first light-emitting device 13a includes two light-emitting sub-structures 1321 (the first light-emitting sub-structure 1321a), and the first isolation opening 12c-1 includes two first sub-isolation openings 12c1-1.

Optionally, as shown in FIG. 17E, the light-emitting structure 132 (the first light-emitting structure 132a) of the first light-emitting device 13a includes four light-emitting sub-structures 1321 (the first light-emitting sub-structure 1321a), and the first isolation opening 12c-1 includes four first sub-isolation openings 12c1-1.

Thus, the quantity of the first light-emitting sub-structures 1321a may be increased. When one of the first light-emitting sub-structures 1321a fails, the remaining first light-emitting sub-structure 1321a may have a larger light-light-emitting area and a better display effect.

Optionally, centroids of the orthogonal projections of four first sub-isolation openings 12c1-1 on the array substrate 11, when connected, define a quadrilateral. That is, the centroids of the orthogonal projections of four first light-emitting sub-structures 1321a on the array substrate 11, when connected, define a quadrilateral. Exemplarily, the quadrilateral may be a trapezoid, a rectangle, a rhombus, a square, etc. Optionally, centroids of the orthogonal projections of four first sub-isolation openings 12c1-1 on the array substrate 11, when connected, define a regular quadrilateral. That is, the centroids of the orthogonal projections of four first light-emitting sub-structures 1321a on the array substrate 11, when connected, define a regular quadrilateral. Thus, an arrangement of the first light-emitting sub-structure 1321a may be made more regular. When one of the first light-emitting sub-structures 1321a fails, the other three first light-emitting sub-structures 1321a may still emit light normally, and a display effect of the other three first light-emitting sub-structures 1321a is not significantly different from a display effect of the four first light-emitting sub-structures 1321a in normal conditions.

In one embodiment, the light-emitting structure 132 of the third light-emitting devices 13c includes the plurality of light-emitting sub-structures 1321, and the third isolation openings 12c-3 include a plurality of third sub-isolation openings 12c1-3. That is, the blue light-emitting structure 132 is separated into a plurality of light-emitting sub-structures 1321. Thus, it is beneficial for improving the display defects of the blue light-emitting device 13.

Optionally, a shape of an orthogonal projection of the third sub-isolation opening 12c1-3 on the array substrate 11 is a polygon. Here, the polygon can be a quadrilateral, a pentagon, a hexagon, a heptagon, an octagon, a nonagon, etc.

Optionally, as shown in FIG. 17D, the light-emitting structure 132 (the third light-emitting structure 132c) of the third light-emitting device 13c includes two light-emitting sub-structures 1321 (the third light-emitting sub-structure 1321c), and the third isolation opening 12 c-3 includes two third sub-isolation openings 12c1-3. A lifespan of the blue light-emitting structure 132 is relatively short. By separating the blue light-emitting structure 132 into two light-emitting sub-structures 1321, not only solving the problem of display defects but also taking into account the lifespan of the blue light-emitting structure 132.

Optionally, as shown in FIGS. 17E and 17F, the light-emitting structure 132 (the third light-emitting structure 132c) of the third light-emitting device 13c includes four light-emitting sub-structures 1321 (the third light-emitting sub-structure 1321c), and the third isolation opening 12 c-3 includes four third sub-isolation openings 12c1-3. Thus, an arrangement of the third light-emitting sub-structure 1321c may be made more regular. When one of the third light-emitting sub-structures 1321c fails, the other three third light-emitting sub-structures 1321c may still emit light normally, and a display effect of the other three third light-emitting sub-structures 1321c is not significantly different from a display effect of the four third light-emitting sub-structures 1321c in normal conditions.

Optionally, centroids of the orthogonal projections of four third sub-isolation openings 12c1-3 on the array substrate 11, when connected, define a quadrilateral. That is, the centroids of the orthogonal projections of four third light-emitting sub-structures 1321c on the array substrate 11, when connected, define a quadrilateral. Exemplarily, the quadrilateral may be a trapezoid, a rectangle, a rhombus, a square, etc. Optionally, centroids of the orthogonal projections of four third sub-isolation openings 12c1-3 on the array substrate 11, when connected, define a regular quadrilateral. That is, the centroids of the orthogonal projections of four third light-emitting sub-structures 132ca on the array substrate 11, when connected, define a regular quadrilateral.

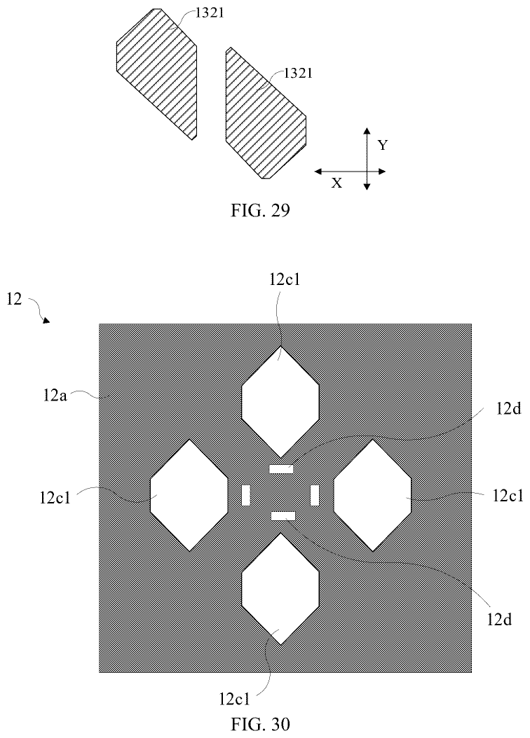

Referring to FIGS. 1 to 36, embodiments of the present disclosure provide a display panel 10. The display panel 10 includes an array substrate and a plurality of light-emitting unit groups 17 arranged on the array substrate 11.

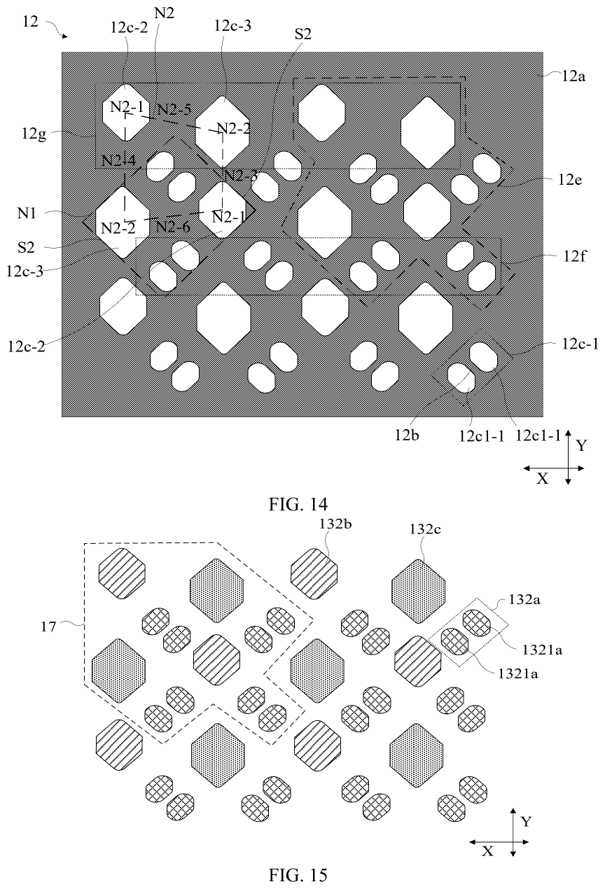

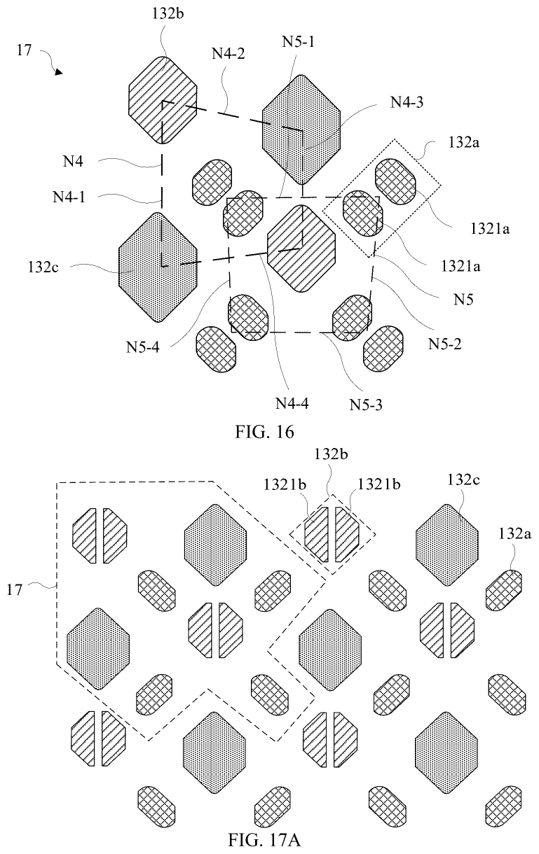

Specifically, as shown in FIGS. 15 and 16, the light-emitting unit group 17 includes a plurality of light-emitting structures 132, and the plurality of light-emitting structures 132 include a plurality of first light-emitting structures 132a, a plurality of second light-emitting structures 132b, and a plurality of third light-emitting structures 132c. Centroids of the plurality of second light-emitting structures 132b and the plurality of third light-emitting structures 132c, when connected, define a first virtual polygon N4, and at least one first light-emitting structure 132a is located in the first virtual polygon N4. The first light-emitting structure 132a, the second light-emitting structure 132b, and the third light-emitting structure 132c are configured to emit light of different colors. Exemplarily, One of the first light-emitting structure 132a, the second light-emitting structure 132b, and the third light-emitting structure 132c emits red light, another emits blue light, and yet another emits green light.

In the same light-emitting unit group 17, at least one light-emitting structure 132 includes a plurality of light-emitting sub-structures 1321 spaced apart, and the plurality of light-emitting sub-structures 1321 are electrically connected to the same driver circuit in the array substrate 11.

In the display panel 110 provided by embodiments of the present disclosure, as the light-emitting structure 132 includes a plurality of sub-structures and the plurality of light-emitting sub-structures 1321 are electrically connected to the same driver circuit, when a certain light-emitting sub-structure 1321 fails (e.g., dark spot failures caused by particle residues and encapsulation failures), it may not affect other light-emitting sub-structures. The other light-emitting sub-structures may still emit light normally, thereby reducing the risk of display defects in the display panel.

The first light-emitting device 13a includes a first electrode 131, the first light-emitting structure 132a, and a second electrode 133 stacked in sequence. the second light-emitting device 13b includes the first electrode 131, the second light-emitting structure 132b, and the second electrode 133 stacked in sequence. the third light-emitting device 13c includes the first electrode 131, the third light-emitting structure 132c, and the second electrode 133 stacked in sequence. the first electrode 131 may be an anode, and the second electrode 133 may be a cathode.

In one embodiment, the display panel 110 may further include an isolation layer 12 arranged on the array substrate 11. The isolation layer 12 includes an isolation structure 12a and a plurality of opening groups 12e. The opening group 12e includes a plurality of isolation openings 12c, and the plurality of isolation openings 12c includes a plurality of first isolation openings 12c-1, a plurality of second isolation openings 12c-2, and a plurality of third isolation openings 12c-3. The plurality of first light-emitting structures 132a are in one-to-one correspondence with the plurality of first isolation openings 12c-1, the plurality of second light-emitting structures 132b are in one-to-one correspondence with the plurality of second isolation openings 12c-2, and the plurality of third light-emitting structures 132c are in one-to-one correspondence with the plurality of third isolation openings 12c-3. At least part of the light-emitting structure 132 is disposed in the corresponding isolation opening 12c. The isolation layer 12 may further include a partition wall 12b located between adjacent light-emitting sub-structures 1321.

Optionally, the second electrode 133 of the light-emitting device 13 is electrically connected to the isolation structure 12.

In one embodiment, in the same light-emitting unit group 17, the light-emitting structure 132 of at least one color includes a plurality of light-emitting sub-structures 1321 spaced apart. Thus, the light-emitting structures 132 of the same color are separated into the plurality of light-emitting sub-structures 1321, thereby maintaining consistency among light-emitting structures 132 of the same color and improving display uniformity.

Optionally, in the same light-emitting unit group 17, the light-emitting structures 132 of at least two colors includes a plurality of light-emitting sub-structures 1321 spaced apart. Thus, compared with the light-emitting structure 132 of only one color separated, the embodiment separates the light-emitting structures 132 of two colors so that the light-emitting structures 132 of two colors may overcome display defects (e.g., dark-spot failures caused by particle residues and encapsulation failures), further reducing the risk of poor display.

Optionally, in the same light-emitting unit group 17, each light-emitting structure 132 includes a plurality of light-emitting sub-structures 1321 spaced apart. Thus, the embodiment separates the light-emitting structures 132 of three colors so that the light-emitting structures 132 of three colors may overcome display defects (e.g., dark spot failures caused by particle residues and encapsulation failures), further reducing the risk of poor display.

In one embodiment, in the same light-emitting structure 132, adjacent sides of two adjacent light-emitting sub-structures 1321 are straight sides and are parallel to each other. Thus, a shape of the light-emitting sub-structure 1321 may be made relatively regular, and at the same time, a space between two light-emitting sub-structures 1321 may be made smaller. Furthermore, when a spacing between the two light-emitting sub-structure 1321 is fixed, the space occupied by the two light-emitting sub-structure 1321 may be maximized, thereby increasing the occupied area of the light-emitting sub-structure 1321 and further improving the aperture ratio.

Optionally, as shown in FIG. 1, the array substrate 11 includes a plurality of scan lines 11b spaced apart along a second direction Y, each of the plurality of scan lines 11b extends along a first direction X intersecting the second direction Y. The light-emitting sub-structure 1321 includes at least one straight side parallel to the second direction Y.

In some embodiments, the second electrode 133 needs to overlap with the isolation layer 12 (e.g., the isolation structure 12a or the partition wall 12b), so as to achieve an electrical connection between the second electrode 133 and the isolation layer 12. Furthermore, during the deposition of the second electrode 133, a deposition source is used to scan along the first direction X. The deposition material is more easily deposited onto a part of the side walls (the side wall parallel to the second direction Y) of the isolation layer 12, thereby enabling a better connection performance between the second electrode 133 and the isolation layer 12.

Optionally, each of the plurality of light-emitting structures 132 includes at least one straight side parallel to the second direction Y.

In one embodiment, in the same light-emitting structure 132, areas of the plurality of light-emitting sub-structures 1321 are the same. Thus, it is beneficial for improving the uniformity of light emission. Optionally, in the same light-emitting structure 132, a shape of each of the plurality of light-emitting sub-structures 1321 is the same. Thus, it not only further improves the uniformity of light emission, but also is beneficial to reduce the large-angle viewing bias.

Optionally, in the same light-emitting structure 132, two adjacent light-emitting sub-structures 1321 are arranged symmetrically. Thus, it not only further improves the uniformity of light emission, but also is beneficial to reduce the large-angle viewing bias. Exemplarily, the two adjacent light-emitting sub-structures 1321 may be arranged symmetrically about a centerline of the partition wall 12b between the two adjacent light-emitting sub-structures 1321.

Optionally, in the same light-emitting structure 132, the two adjacent light-emitting sub-structures 1321 are arranged symmetrically centered. Thus, it not only further improves the uniformity of light emission, but also is beneficial to reduce the large-angle viewing bias. Exemplarily, the two adjacent light-emitting sub-structures 1321 may be arranged symmetrically about the centroid of the partition wall 12b between the two adjacent light-emitting sub-structure 1321s 12c1.

In one embodiment, areas of at least two light-emitting sub-structures 1321 of at least one light-emitting structure 132 are not equal. Thus, it is beneficial for the designers to carry out special designs for an arrangement of the light-emitting sub-structure 1321 based on actual requirements, thereby enhancing the display effect.

Optionally, as shown in FIG. 13, the array substrate 11 may further include a first wiring line 11d. In at least two light-emitting sub-structures 1321, an orthogonal projection of at least one light-emitting sub-structure 1321 on the array substrate 11 overlaps with an orthogonal projection of the first wiring line 11d on the array substrate 11, and the orthogonal projection of at least one light-emitting sub-structure 1321 on the array substrate 11 does not overlap with the orthogonal projection of the first wiring line 11d on the array substrate 11.

Optionally, the orthogonal projection of at least one light-emitting sub-structure 1321 on the array substrate 11 overlaps with the orthogonal projection of the first wiring line 11d on the array substrate 11, and an overlapping projection is arranged symmetrically about a centerline of the orthogonal projection of at least one light-emitting sub-structure 1321 on the array substrate 11. Thus, it is equivalent to designing the separation of the light-emitting structure 132 differently based on the overlapping situation between the light-emitting structure 132 and the first wiring line 11d (whether overlap or not). It is beneficial for the designers to design the area of light-emitting sub-structure 1321 differently based on the overlapping situation between light-emitting sub-structure 1321 and first wiring line 11d. The wiring lines in the array substrate 11 are highly reflective. When the first wiring line 11d is located below the light-emitting sub-structure 1321, it can have a certain impact on the light-emitting effect of the light-emitting sub-structure 1321. Therefore, when the first wiring line 11d overlaps with the light-emitting structure 132, designers need to carry out some special designs to reduce the impact of the first wiring line 11d on the light emission effect. The above-mentioned differentiated designs are beneficial for reducing the impact of the first wiring line 11d on the light emission effect.

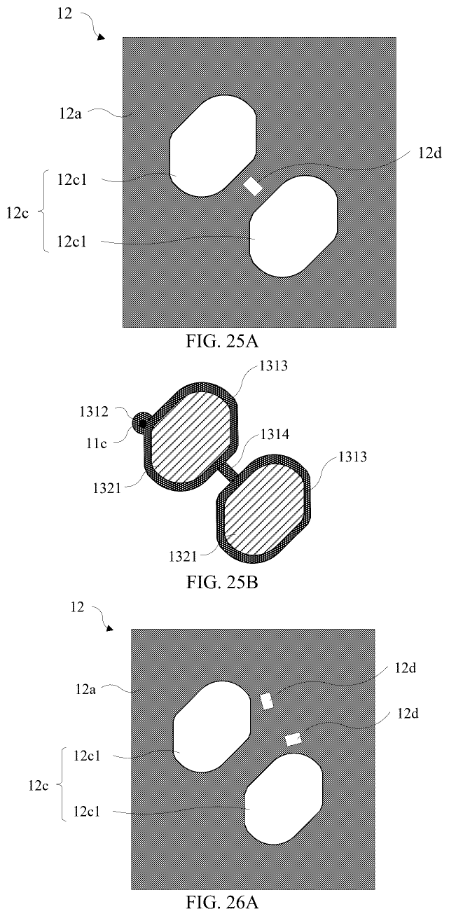

In one embodiment, referring to FIG. 3, the first electrode 131 corresponding to each of the plurality of light-emitting structures 132 includes a plurality of sub-electrodes 1313. The plurality of sub-electrodes 1313 are in one-to-one correspondence with the plurality of light-emitting sub-structures 1321. Furthermore, referring to FIG. 25B, in the same first electrode 131, the adjacent sub-electrodes 1313 are connected by a connection line 1314. Thus, when a short circuit defect occurs in a certain sub-electrode 1313, the connection line 1314 may be burned out by laser, ensuring that the remaining sub-electrodes 1313 continue to operate normally and thereby improving display defects caused by short circuits.

Optionally, as shown in FIGS. 25B, 26B, 27, 28, 31, 33, 34, and 36, the display panel 110 may further include a plurality of conductive structures 11c corresponding to the plurality of first electrodes 131. Each of the plurality of first electrodes 131 is electrically connected to the corresponding driver circuit through at least one conductive structure 11c. For example, the conductive structure 11c may be a through-hole structure. The conductive structure 11c is connected to a protruding portion 1312 of the first electrode 131. Specifically, each of the sub-electrodes 1313 of the first electrode 131 is connected to the protruding portion 1312, and the protruding portion 1312 is connected to the conductive structure 11c, thereby enabling each sub-electrode 1313 to be electrically connected to the corresponding driver circuit.

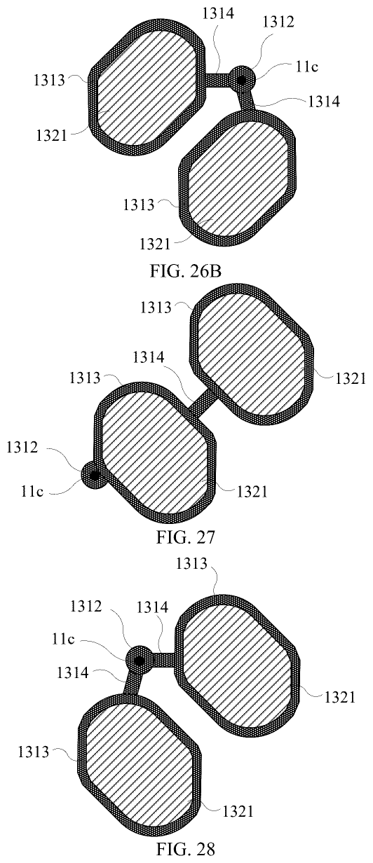

In one embodiment, as shown in FIGS. 25B, 26B, 27, and 28, at least one light-emitting structure 132 includes two light-emitting sub-structures 1321, and the first electrode 131 corresponding to the light-emitting structure 132 includes two sub-electrodes 1313 connected by the connection line 1314. The light-emitting structure 132 here may be the first light-emitting structure 132a, the second light-emitting structure 132b, or the third light-emitting structure 132c. In an example, as shown in FIGS. 26B and 28, the conductive structure 11c is located between two sub-electrodes 1313, and is connected to the connection line 1314. Furthermore, each sub-electrode 1313 is connected to the conductive structure 11 c through a connection line 1314. In another example, as shown in FIGS. 25B and 27, the conductive structure 11c is connected to a side, facing away from another sub-electrode 1313, of one sub-electrode 1313. Furthermore, two sub-electrodes 1313 are connected by a connection line 1314. Optionally, as shown in FIGS. 25A and 25B, at least part of an orthogonal projection of the connection line 1314 on the array substrate 11 is located in an orthogonal projection of the partition wall 12b on the array substrate 11.

In one embodiment, as shown in FIGS. 31, 33, 34, and 36, at least one light-emitting structure 132 includes four light-emitting sub-structures 1321. The first electrode 131 corresponding to the light-emitting structure 132 includes four sub-electrodes 1313. Each sub-electrode 313 is directly connected to at least one connection line 1314. The light-emitting structure 132 here may be the first light-emitting structure 132a, the second light-emitting structure 132b, or the third light-emitting structure 132c. Optionally, the centroids of four sub-electrodes 1313, when connected, define a third virtual quadrilateral N3. The third virtual quadrilateral N3, may be a square, rectangle, rhombus, trapezoid, etc. Optionally, the conductive structure 11c is configured to electrically connect four sub-electrodes 1313 to the corresponding driver circuit.

Optionally, as shown in FIG. 31, the conductive structure 11c is located inside the third virtual quadrilateral N3, and each sub-electrode 1313 is connected to the conductive structure 11c through one connection line 1314. Specifically, each sub-electrode 1313 is connected to a same protruding portion 1312 through a connection line 1314, and this protruding portion 1312 is connected to the conductive structure 11c. Thus, when a short circuit defect occurs in a certain sub-electrode 1313, the connection line 1314 between this sub-electrode 1313 and the protruding portion 1312 may be burned out, ensuring that the other three light-emitting sub-structures 1321 to emit light normally.

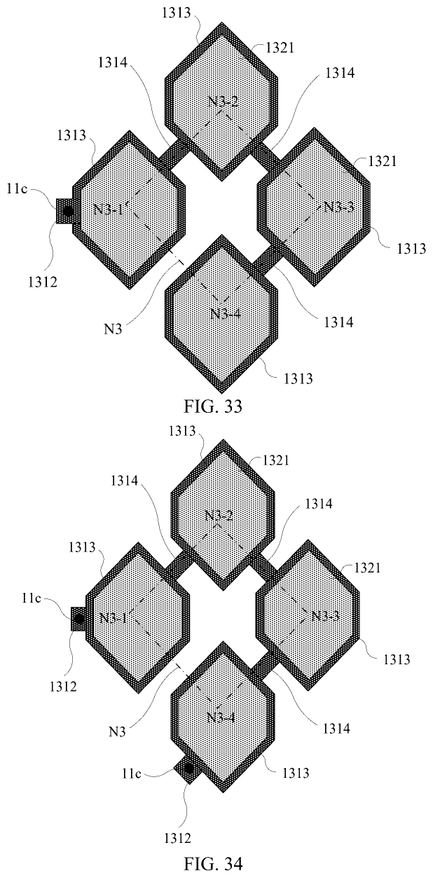

Optionally, as shown in FIG. 33, the third virtual quadrilateral N3 includes a first corner N3-1, a second corner N3-2, a third corner N3-3 and a fourth corner N3-4. The conductive structure 11c is located outside the third virtual quadrilateral N3 and is connected to the sub-electrode 1313 at the first corner N3-1. A connection line 1314 is provided to connect the sub-electrode 1313 at the first corner N3-1 to the sub-electrode 1313 at the second corner N3-2r, a connection line 1314 is provided to connect the sub-electrode 1313 at the second corner N3-2 to the sub-electrode 1313 at the third corner N3-3, and a connection line 1314 is provided to connect the sub-electrode 1313 at the third corner N3-3 to the sub-electrode 1313 at the fourth corner N3-4. Thus, when a short circuit defect occurs in the sub-electrode 1313 located at the fourth corner N3-4, the connection line 1314 between the sub-electrode 1313 at the fourth corner N3-4 and the sub-electrode 1313 at the third corner N3-3 may be burned out, the sub-electrodes 1313 at the first corner N3-1, the second corner N3-2, and the third corner N3-3 may emit light normally. When a short circuit defect occurs in the sub-electrode 1313 located at the third corner N3-3, the connection line 1314 between the sub-electrode 1313 at the third corner N3-3 and the sub-electrode 1313 at the second corner N3-2 may be burned out, the sub-electrodes 1313 at the first corner N3-1 and the second corner N3-2 may emit light normally. When a short circuit defect occurs in the sub-electrode 1313 located at the second corner N3-2, the connection line 1314 between the sub-electrode 1313 at the first corner N3-1 and the sub-electrode 1313 at the second corner N3-2 may be burned out, the sub-electrodes 1313 at the first corner N3-1 may emit light normally.

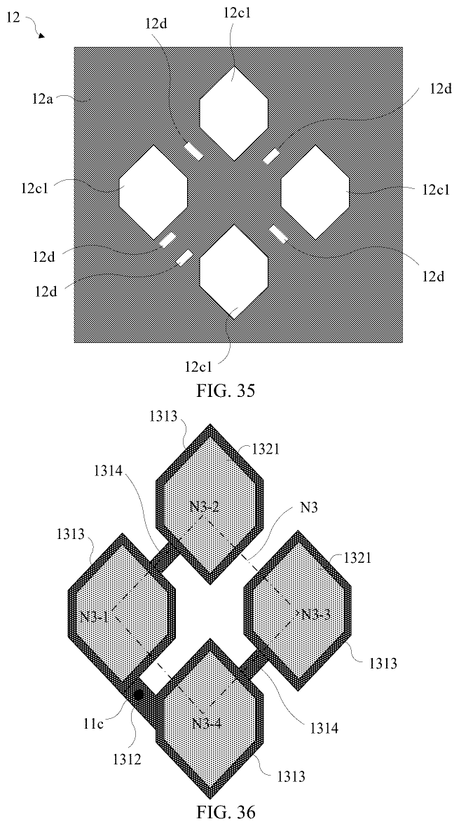

Optionally, as shown in FIG. 34, the third virtual quadrilateral N3 includes the first corner N3-1, the second corner N3-2, the third corner N3-3 and the fourth corner N3-4. The conductive structure 11c is located outside the third virtual quadrilateral N3. The sub-electrode 1313 at the first corner N3-1 and the sub-electrode 1313 at the fourth corner N3-4 are connected to one conductive structure 11c respectively. One connection line 1314 is provided to connect the sub-electrode 1313 at the first corner N3-1 and the sub-electrode 1313 at the second corner N3-2, and one connection line 1314 is provided to connect between the sub-electrode 1313 at the third corner N3-3 and the sub-electrode 1313 at the fourth corner N3-4.

In an example, no connection line 1314 is arranged between the sub-electrode 1313 located at the second corner N3-2 and the sub-electrode 1313 located at the third corner N3-3. Thus, when a short circuit defect occurs in the sub-electrode 1313 located at the second corner N3-2, the connection line 1314 between the sub-electrode 1313 at the second corner N3-2 and the sub-electrode 1313 at the first corner N3-1 may be burned out, the sub-electrodes 1313 at the first corner N3-1, the fourth corner N3-4, and the third corner N3-3 may emit light normally. When a short circuit defect occurs in the sub-electrode 1313 located at the third corner N3-3, the connection line 1314 between the sub-electrode 1313 at the third corner N3-3 and the sub-electrode 1313 at the fourth corner N3-4 may be burned out, the sub-electrodes 1313 at the first corner N3-1, the second corner N3-2, and the third corner N3-3 may emit light normally. When a short circuit defect occurs in the sub-electrode 1313 located at the first corner N3-1, the connection line 1314 between the sub-electrode 1313 at the first corner N3-1 and the connected protruding portion 1312 may be burned out, the sub-electrodes 1313 at the third corner N3-3 and the fourth corner N3-4 may emit light normally. When a short circuit defect occurs in the sub-electrode 1313 located at the fourth corner N3-4, the connection line 1314 between the sub-electrode 1313 at the fourth corner N3-4 and the connected protruding portion 1312 may be burned out, the sub-electrodes 1313 at the first corner N3-1 and the second corner N3-2 may emit light normally.

In an example, as shown in FIG. 34, one connection line 1314 is provided to connect the sub-electrode 1313 at the second corner N3-2 to the sub-electrode 1313 at the third corner N3-3. When a short circuit defect occurs in the sub-electrode 1313 located at the second corner N3-2, the connection line 1314 between the sub-electrode 1313 at the second corner N3-2 and the sub-electrode 1313 at the first corner N3-1 may be burned out, and the connection line 1314 between the sub-electrode 1313 at the second corner N3-2 and the sub-electrode 1313 at the third corner N3-3 may be burned out, the sub-electrodes 1313 at the first corner N3-1, the fourth corner N3-4, and the third corner N3-3 may emit light normally. When a short circuit defect occurs in the sub-electrode 1313 located at the third corner N3-3, the connection line 1314 between the sub-electrode 1313 at the third corner N3-3 and the sub-electrode 1313 at the fourth corner N3-4 may be burned out, and the connection line 1314 between the sub-electrode 1313 at the third corner N3-3 and the sub-electrode 1313 at the second corner N3-2 may be burned out, the sub-electrodes 1313 at the first corner N3-1, the second corner N3-2, and the third corner N3-3 may emit light normally. When a short circuit defect occurs in the sub-electrode 1313 located at the first corner N3-1, the connection line 1314 between the sub-electrode 1313 at the first corner N3-1 and the connected protruding portion 1312 may be burned out, and the connection line 1314 between the sub-electrode 1313 at the first corner N3-1 and the sub-electrode 1313 at the second corner N3-2 may be burned out, the sub-electrodes 1313 at the third corner N3-3 and the fourth corner N3-4 may emit light normally. When a short circuit defect occurs in the sub-electrode 1313 located at the fourth corner N3-4, the connection line 1314 between the sub-electrode 1313 at the fourth corner N3-4 and the connected protruding portion 1312 may be burned out, and the connection line 1314 between the sub-electrode 1313 at the fourth corner N3-4 and the sub-electrode 1313 at the third corner N3-3 may be burned out, the sub-electrodes 1313 at the first corner N3-1 and the second corner N3-2 may emit light normally.

Optionally, as shown in FIG. 36, the third virtual quadrilateral N3 includes the first corner N3-1, the second corner N3-2, the third corner N3-3 and the fourth corner N3-4. One protruding portion 1312 is arranged between the sub-electrode 1313 at the first corner N3-1 and the sub-electrode 1313 at the fourth corner N3-4. The sub-electrode 1313 at the first corner N3-1 and the sub-electrode 1313 at the fourth corner N3-4 are connected to the protruding portion 1312, thereby facilitating connection to the conductive structure 11c, and the conductive structure 11c is located between two sub-electrodes 1313. One connection line 1314 is provided to connect the sub-electrode 1313 at the first corner N3-1 to the sub-electrode 1313 at the second corner N3-2, one connection line 1314 is provided to connect the sub-electrode 1313 at the third corner N3-3 to the sub-electrode 1313 at the fourth corner N3-4. When a short circuit defect occurs in the sub-electrode 1313 located at the second corner N3-2, the connection line 1314 between the sub-electrode 1313 at the second corner N3-2 and the sub-electrode 1313 at the first corner N3-1 may be burned out, the sub-electrodes 1313 at the first corner N3-1, the fourth corner N3-4, and the third corner N3-3 may emit light normally. When a short circuit defect occurs in the sub-electrode 1313 located at the third corner N3-3, the connection line 1314 between the sub-electrode 1313 at the third corner N3-3 and the sub-electrode 1313 at the fourth corner N3-4 may be burned out, the sub-electrodes 1313 at the first corner N3-1, the second corner N3-2, and the third corner N3-3 may emit light normally. When a short circuit defect occurs in the sub-electrode 1313 located at the first corner N3-1, the connection line 1314 between the sub-electrode 1313 at the first corner N3-1 and the connected protruding portion 1312 may be burned out, the sub-electrodes 1313 at the third corner N3-3 and the fourth corner N3-4 may emit light normally. When a short circuit defect occurs in the sub-electrode 1313 located at the fourth corner N3-4, the connection line 1314 between the sub-electrode 1313 at the fourth corner N3-4 and the connected protruding portion 1312 may be burned out, the sub-electrodes 1313 at the first corner N3-1 and the second corner N3-2 may emit light normally.

In one embodiment, an orthogonal projection of a metal layer in the array substrate 11 does not overlap with at least part of an orthogonal projection of the connection line 1314. During the process of burning the connection line 1314 out, the laser may also be illuminated from the back of the display panel 10 onto the connection line 1314, thereby causing the connection line 1314 to be burned out. In this case, the metal layer in the array substrate 11 may not overlap with the laser irradiation region of the connection line 1314 to prevent the laser from being blocked.

In one embodiment, the isolation structure 12a is provided with a via hole 12d corresponding to the connection line 1314. Specifically, an orthogonal projection of a hole wall of the via hole 12d on the array substrate 11 overlaps an orthogonal projection of the corresponding connection line 1314 on the substrate. Thus, the connection line 1314 may be directly illuminated from the front of display panel 10 through via hole 12d. The via hole 12d may also be reused as a light-transmitting hole, thereby increasing light transmittance of display panel 10.

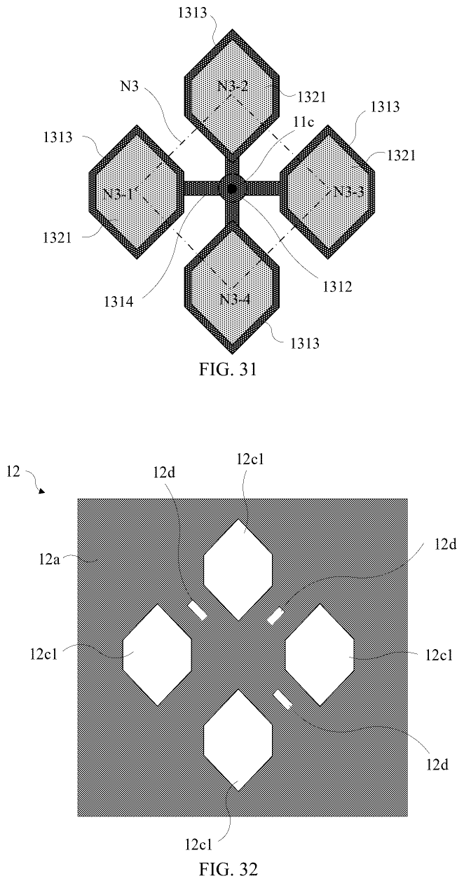

In an example, as shown in FIGS. 25A and 25B, a via hole 12d is provided between two sub-isolation openings 12c1. In an example, as shown in FIGS. 26A and 26B, a via hole 12d is provided on an outer side of each sub-isolation opening 12c1. In an example, as shown in FIGS. 30 and 31, four via holes 12d are provided between four sub-isolation openings 12c1, and each via hole 12d corresponds to one of the sub-isolation opening 12c1. In an example, as shown in FIGS. 32 and 33, a via hole 12d is provided between the sub-isolation opening 12c1 at the first corner N3-1 and the sub-isolation opening 12c1 at the second corner N3-2, a via hole 12d is provided between the sub-isolation opening 12c1 at the second corner N3-2 and the sub-isolation opening 12c1 at the third corner N3-3, and a via hole 12d is provided between the sub-isolation opening 12c1 at the third corner N3-3 and the sub-isolation opening 12c1 at the fourth corner N3-4. In an example, as shown in FIGS. 35 and 36, a via hole 12d is provided between the sub-isolation opening 12c1 at the first corner N3-1 and the sub-isolation opening 12c1 at the second corner N3-2, a via hole 12d is provided between the sub-isolation opening 12c1 at the second corner N3-2 and the sub-isolation opening 12c1 at the third corner N3-3, a via hole 12d is provided between the sub-isolation opening 12c1 at the third corner N3-3 and the sub-isolation opening 12c1 at the fourth corner N3-4, and two via holes 12d are provided between the sub-isolation opening 12c1 at the first corner N3-1 and the sub-isolation opening 12c1 at the fourth corner N3-4.

In one embodiment, as shown in FIG. 9, an orthogonal projection of the first electrode 131 corresponding to the light-emitting structure 132 including the plurality of light-emitting sub-structures 1321 on the array substrate 11 covers orthogonal projections of the plurality of light-emitting sub-structures 1321 corresponding to the light-emitting structure 132 on the array substrate 11 and an orthogonal projection of the partition wall 12b corresponding to the light-emitting structure 132 on the array substrate 11. That is, the first electrode 131 is a complete block-like structure. Thus, it is beneficial for increasing an area of the first electrode 131 and reducing a resistance of the first electrode 131.

Optionally, as shown in FIG. 8, the first electrode 131 corresponding to the first light-emitting structure 132a includes a first main body portion 1311a, and an orthogonal projections of each first light-emitting sub-structure 1321a of the first light-emitting structure 132a on the array substrate 11 is located in an orthogonal projection of the first main body portion 1311a on the array substrate 11. For example, a shape of the first main body portion 1311a may be a regular block-like shape.

Optionally, the first main body portion 1311a is electrically connected to the driver circuit in the array substrate 11 through a conductive structure 11c. The array substrate 11 is provided with a plurality of first driver circuits 11a, a plurality of second driver circuits, and a plurality of third driver circuits. The first electrode 131 of the first light-emitting device 13a is electrically connected to the first driver circuit 11a, the first electrode 131 of the second light-emitting device 13b is electrically connected to the second driver circuit, and the first electrode 131 of the third light-emitting device 13c is electrically connected to the third driver circuit.

Optionally, the first electrode 131 may further include a first protruding portion 1312a connected to the first main body portion 1311a, and the first protruding portion 1312a is electrically connected to the driver circuit in the array substrate 11 through the conductive structure 11c. In this way, an orthogonal projection of the conductive structure 11c connected to the first protruding portion 1312a on the array substrate 11 is located outside an orthogonal projection of the first light-emitting structure 132a on the array substrate 11, thereby ensuring that the conductive structure 11c does not adversely affect the light emission of the first light-emitting structure 132a.

Optionally, as shown in FIG. 9, an orthogonal projection of the first protruding portion 1312a on the array substrate 11 is located in an orthogonal projection of the isolation structure 12a on the array substrate 11.

In one embodiment, as shown in FIGS. 3, 4, and 5, the isolation structure 12a includes a conductive portion 121 and a barrier portion 122 stacked in a direction away from the array substrate 11, and an orthogonal projection of the conductive portion 121 on the array substrate 11 is located in an orthogonal projection of the barrier portion 122 on the array substrate 11. At least part of the plurality of second electrodes 133 is in contact with the conductive portion 121. In this way, the isolation structure 12a may be configured as a wiring line to connect the second electrode 133 to the driver circuit, thereby optimizing the wiring line arrangement within the display region of the display panel 10.

Optionally, the second electrode 133 corresponding to the light-emitting structure 132 including the plurality of light-emitting sub-structures 1321 includes a plurality of sub-electrode portions 1331 in one-to-one correspondence with the plurality of light-emitting sub-structures 1321, and each sub-electrode portions 1331 is in contact with the conductive portion 121. Thus, each sub-electrode portion 1331 is electrically connected to the isolation structure 12a respectively, preventing damage to a certain sub-electrode portion 1331 from affecting the other sub-electrode portions 1331, thereby enhancing the light-emitting reliability of the display panel 10. Optionally, at least part of an outer edge of each sub-electrode portions 1331 covers a side wall, close to the isolation opening 12c, of the conductive portion 121. Thus, the contact area between the sub-electrode portion 1331 and the conductive portion 121 may be larger, thereby reducing the electrically connected resistance. Optionally, in the same light-emitting device 13, a maximum distance between the outer edge of each sub-electrode portion 1331 and the array substrate 11 is the same. In other words, the overlapping height of each sub-electrode portion 1331 on the conductive portion 121 is the same. Here, due to the influence of the manufacturing process, “approximately equal” may also be regarded as equal. The above settings are beneficial to ensuring that the electrical bonding resistance between each sub-electrode portion 1331 and the conductive portion 121 remains consistent, and improving the uniformity of light emission.

Optionally, the display panel 10 may further include a plurality of first encapsulation portions 14a in one-to-one correspondence with the plurality of first light-emitting structures 132. Each of the plurality of first encapsulation portions 14a is arranged on a side, facing away from the array substrate 11, of the corresponding first light-emitting structure 132a. Exemplarily, the first encapsulation portion 14a may be an inorganic film layer. Optionally, an orthogonal projection of a first encapsulation portions 14a on the array substrate 11 covers an orthogonal projection of the first light-emitting sub-structure 1321a corresponding to the first light-emitting structure 132a on the array substrate 11, and an orthogonal projection of the partition wall 12b corresponding to the first light-emitting structure 132a on the array substrate 11. That is, the first encapsulation portion 14a is a continuous layer structure. Thus, the contact area between the first encapsulation portion 14a and the other layers in the display panel 10 may be increased, thereby enhance the connection stability of the first encapsulation portion 14a, and improving the encapsulation reliability.

Optionally, a light-emitting material layer 161 and an electrode material layer 162 stacked are further provided between the partition wall 12b located between the two adjacent first light-emitting sub-structures 1321a and the first encapsulation portion 14a. In one embodiment, the first encapsulation portion 14a includes a plurality of first sub-encapsulation portions 141a spaced apart, the plurality of first sub-encapsulation portions 141a are in one-to-one correspondence with the plurality of first light-emitting sub-structures 1321. The plurality of first sub-encapsulation portions 141a are disposed on a side, facing away from the array substrate 11, of the corresponding first light-emitting sub-structures 1321a. Thus, it is equivalent to separately encapsulating each light-emitting sub-structure 1321. In this way, when the encapsulation of one first sub-encapsulation portion 141a fails, it will not affect the encapsulation performance of other first sub-encapsulation portions 141a, ensuring that other light-emitting sub-structures 1321 to emit light normally, thereby reducing the risk of display defects in the display panel 10.

In one embodiment, the display panel 10 may further include a plurality of second encapsulation portions 14b, and the plurality of second encapsulation portions 14b are in one-to-one correspondence with the plurality of second light-emitting structures 132. The plurality of second encapsulation portions 14b are disposed on a side, facing away from the array substrate 11, of the corresponding second light-emitting structures 132b. Exemplarily, the second encapsulation portion 14b may be an inorganic film layer. In one embodiment, an orthogonal projection of the second encapsulation portion 14b on the array substrate 11 covers an orthogonal projection of the second light-emitting sub-structure 1321b corresponding to the second light-emitting structure 132b on the array substrate 11, and an orthogonal projection of the partition wall 12b corresponding to the second light-emitting structure 132b on the array substrate 11. That is, the second encapsulation portion 14b is a continuous layer structure. Thus, the contact area between the second encapsulation portion 14b and the other layers in the display panel 10 may be increased, thereby enhancing the connection stability of the second encapsulation portion 14b, and improving the encapsulation reliability.

Optionally, a light-emitting material layer 161 and an electrode material layer 162 stacked are further provided between the partition wall 12b located between two adjacent second light-emitting sub-structures 1321b, and the second encapsulation portion 14 b. In one embodiment, the second encapsulation portion 14b includes a plurality of second sub-encapsulation portions (not shown in the figure) spaced apart, and the plurality of second sub-encapsulation portions are in one-to-one correspondence with the plurality of second light-emitting sub-structures 1321. The second sub-encapsulation portion is disposed on a side, facing away from the array substrate 11, of the corresponding second light-emitting sub-structure 1321b. Thus, it is equivalent to separately encapsulating each second light-emitting sub-structure 1321b. In this way, when the encapsulation of one second sub-encapsulation portion fails, it will not affect the encapsulation performance of other second sub-encapsulation portions, ensuring that other second light-emitting sub-structures 1321bto emit light normally, thereby reducing the risk of display defects in the display panel 10.

In one embodiment, the display panel 10 may further include a plurality of third encapsulation portions 14c in one-to-one correspondence with the plurality of third light-emitting structures 132c. The third encapsulation portion 14c is provided on a side, facing away from the array substrate 11, of the corresponding third light-emitting structure 132c. Exemplarily, the third encapsulation portion 14c may be an inorganic film layer. In one embodiment, an orthogonal projection of the third encapsulation portion 14c on the array substrate 11 covers an orthogonal projection of the third light-emitting sub-structure 1321c corresponding to the third light-emitting structure 132c on the array substrate 111, and an orthogonal projection of the partition wall 12b corresponding to the third light-emitting structure 132c on the array substrate 11. That is, the third encapsulation portion 14c is a continuous layer structure. Thus, the contact area between the third encapsulation portion 14c and the other layers in the display panel 10 may be increased, thereby enhancing the connection stability of the third encapsulation portion 14c, and improving the encapsulation reliability.

Optionally, a light-emitting material layer 161 and an electrode material layer 162 stacked are further provided between the partition wall 12b located between the two adjacent third light-emitting sub-structures 1321c, and the third encapsulation portion 14c. In one embodiment, the third encapsulation portion 14c includes a plurality of third sub-encapsulation portions (not shown in the figure) spaced apart in one-to-one correspondence with the plurality of third light-emitting sub-structures 1321. The third sub-encapsulation portion is disposed on a side, facing away from the array substrate 11, of the corresponding third light-emitting sub-structure 1321c. Thus, it is equivalent to separately encapsulating each third light-emitting sub-structure 1321c. In this way, when the encapsulation of one third sub-encapsulation portion fails, it will not affect the encapsulation performance of other third sub-encapsulation portions, ensuring that other third light-emitting sub-structures 1321c to emit light normally, thereby reducing the risk of display defects in the display panel 10.

In one embodiment, a wavelength of light emitted by the first light-emitting structure 132a ranges from 505 nm to 545 nm, that is, the first light-emitting device 13a is a green light-emitting device 13. A wavelength of light emitted by the plurality of second light-emitting structures 132b ranges from 600 nm to 650 nm, that is, the second light-emitting device 13b is a red light-emitting device 13. A wavelength of light emitted by the plurality of third light-emitting structures 132c ranges from 440 nm to 480 nm, that is, the third light-emitting device 13c is a blue light-emitting device 13.

In the same light-emitting unit group 17, each of the plurality of second light-emitting structures 132b includes a plurality of second light-emitting sub-structures 1321b. That is, the red light-emitting structure 132 is separated into a plurality of light-emitting sub-structures 1321. In an example, as shown in FIGS. 15 and 16, a quantity of the second light-emitting sub-structures 1321bin the same second light-emitting structure 132b is the same to a quantity of the second light-emitting structures 132b in the same light-emitting unit group 17, and the quantity thereof is two. In another example, the quantity of the second light-emitting sub-structures 1321b in the same second light-emitting structure 132b is an integer multiple of the quantity of the third light-emitting structures 132c in the same light-emitting unit group 17. Specifically, as shown in FIG. 17, the quantity of the second light-emitting sub-structures 1321b in the same second light-emitting structure 132b is the same to the quantity of the third light-emitting structure 132c in the same light-emitting unit group 17. As shown in FIG. 17E, the quantity of the second light-emitting sub-structure 1321bin the same second light-emitting structure 132 b is twice the quantity of the third light-emitting structure 132c in the same light-emitting unit group 17. Optionally, the quantity of the second light-emitting sub-structures 1321b in the same second light-emitting structure 132b is twice the quantity of the third light-emitting structures 132c in the same light-emitting unit group 17. Specifically, the quantity of the second light-emitting sub-structures 1321bin the same second light-emitting structure 132b is four, and the quantity of the third light-emitting structures 132c in the same light-emitting unit group 17 is two.

Optionally, a shape of the second light-emitting sub-structure 1321b is a polygon. Exemplarily, the shape of the second light-emitting sub-structure 1321b may be a quadrilateral, a pentagon, a hexagon, a heptagon, and an octagon, etc.

Optionally, as shown in FIG. 17A, the second light-emitting structure 132b includes two second light-emitting sub-structures 1321b. Optionally, as shown in FIG. 17E, the second light-emitting structure 132b includes four second light-emitting sub-structures 1321b. Optionally, centroids of four second light-emitting sub-structures 1321b, when connected, define a quadrilateral. Exemplarily, the centroids of four second light-emitting sub-structures 1321b, when connected, define a square.

In one embodiment, in the same light-emitting unit group 17, each of the plurality of first light-emitting structures 132a includes a plurality of first light-emitting sub-structures 1321a. Optionally, as shown in FIG. 17E, the quantity of the first light-emitting sub-structures 1321a in the same first light-emitting structure 132 a is the same to the quantity of the first light-emitting structures 132a in the same light-emitting unit group 17, and quantity thereof is four.

Optionally, a shape of a first light-emitting sub-structure 1321a is a polygon. Exemplarily, the shape of the first light-emitting sub-structure 1321a may be a quadrilateral, a pentagon, a hexagon, a heptagon, and an octagon, etc.

Optionally, as shown in FIGS. 17C and 17D, the first light-emitting structure 132a includes two first light-emitting sub-structures 1321a.

In one embodiment, in the same light-emitting unit group 17, the third light-emitting structure 132 c includes a plurality of third light-emitting sub-structures 1321c. In an example, as shown in FIG. 17B, the quantity of the third light-emitting sub-structures 1321c in the same third light-emitting structure 132c is the same to the quantity of the third light-emitting structures 132c in the same light-emitting unit group 17, and the quantity thereof is two.

In another example, the quantity of the third light-emitting sub-structures 1321c in the same third light-emitting structure 132c is an integer multiple of the quantity of the second light-emitting structures 132b in the same light-emitting unit group 17. Specifically, as shown in FIG. 17B, the quantity of the third light-emitting sub-structure 1321c in the same third light-emitting structure 132c is the same to the quantity of the second light-emitting structure 132b in the same light-emitting unit group 17. As shown in FIG. 17E, the quantity of the third light-emitting sub-structure 1321c in the same third light-emitting structure 132c is twice the quantity of the second light-emitting structure 132b in the same light-emitting unit group 17. Optionally, as shown in FIGS. 17E and 17F, the quantity of the third light-emitting sub-structure 1321c in the same third light-emitting structure 132c is twice the quantity of the second light-emitting structure 132b in the same light-emitting unit group 17. The quantity of the third light-emitting sub-structure 1321c in the same third light-emitting structure 132c is four, the quantity of the second light-emitting structure 132b in the same light-emitting unit group 17 is two.

Optionally, a shape of a third light-emitting sub-structure 1321c is a polygon. Exemplarily, the shape of the third light-emitting sub-structure 1321c may be a quadrilateral, a pentagon, a hexagon, a heptagon, and an octagon, etc.

Optionally, as shown in FIG. 17D, the third light-emitting structure 132c includes two third light-emitting sub-structures 1321c. Optionally, as shown in FIG. 17E, the third light-emitting structure 132c includes four third light-emitting sub-structures 1321c. Optionally, centroids of four third light-emitting sub-structures 1321c, when connected, define a quadrilateral, such as a square.

In one embodiment, as shown in FIG. 17C, in the same light-emitting unit group 17, the quantity of the first light-emitting sub-structures 1321a in the first light-emitting structure 132a is the same to the quantity of the second light-emitting sub-structures 1321b in the second light-emitting structure 132b, and is two. Optionally, as shown in FIG. 17D, the quantity of the first light-emitting sub-structures 1321a in the first light-emitting structure 132a is the same to the quantity of the third light-emitting sub-structures 1321c in the third light-emitting structure 132c, and is two. Optionally, as shown in FIG. 17C, the quantity of the first light-emitting sub-structures 1321a in the first light-emitting structure 132 a is two, the quantity of the second light-emitting sub-structures 1321b in the second light-emitting structure 132b is two. Optionally, as shown in FIG. 17D, the quantity of the first light-emitting sub-structures 1321a in the first light-emitting structure 132a is two, the quantity of the second light-emitting sub-structures 1321b in the second light-emitting structure 132b is two, and the quantity of the third light-emitting sub-structures 1321c in the third light-emitting structure 132c is two. Optionally, as shown in FIG. 17E, the quantity of the first light-emitting sub-structures 1321a in the first light-emitting structure 132a is four, the quantity of the second light-emitting sub-structures 1321bin the second light-emitting structure 132b is four, and the quantity of the third light-emitting sub-structures 1321c in the third light-emitting structure 132c is four. Optionally, as shown in FIG. 17F, the quantity of the first light-emitting sub-structures 1321a in the first light-emitting structure 132a is two, the quantity of the second light-emitting sub-structures 1321b in the second light-emitting structure 132b is four, and the quantity of the third light-emitting sub-structures 1321c in the third light-emitting structure 132c is four.

In one embodiment, as shown in FIG. 16, the first virtual polygon N4 is a quadrilateral. Optionally, the first virtual polygon N4 includes a fifth edge N4-1 and a seventh edge N4-3 parallel to each other, and a sixth edge N4-2 and an eighth edge N4-4 connecting the fifth edge N4-1 and the seventh edge N4-3. Optionally, a length of the fifth edge N4-1 is greater than a length of the seventh edge N4-3.

Optionally, centroids of the plurality of first light-emitting structures 132a, when connected, define a second virtual polygon N5, and one of the second light-emitting structures 132b is located in the second virtual polygon N5.

Optionally, the second virtual polygon N5 is a quadrilateral. The second virtual polygon includes a ninth edge N5-1 and an eleventh edge N5-3 parallel to each other, and a tenth edge N5-2 and a twelfth edge N5-4 connecting the ninth edge N5-1 and the eleventh edge N5-3. Optionally, a length of the ninth edge N5-1 is greater than a length of the eleventh edge N5-3.

Optionally, the first virtual polygon N4 and the second virtual polygon N5 are trapezoids.

In one embodiment, as shown in FIG. 6, a spacing between two adjacent light-emitting structures 132 is a third spacing c. In the same light-emitting structure 132, a spacing between the two adjacent light-emitting sub-structures 1321 is a fourth spacing d, and the third spacing c and the fourth spacing d are not equal. Thus, by making the third spacing c and the fourth spacing d unequal, it is beneficial for designers to adaptively adjust the positioning of the light-emitting structure 132 based on actual requirements. For example, when the fourth spacing d is smaller than the third spacing c, it is beneficial for maximizing the aperture ratio and minimizing the loss of separating light-emitting structure on the aperture ratio; and when the fourth spacing d is larger than the third spacing c, it is beneficial to set the conductive structure 11c in the area between adjacent light-emitting sub-structures for connecting the anode and the driver circuit, thereby facilitating the designers to set the position of the conductive structure 11c based on actual requirements and reducing the restrictions on the setting position of the conductive structure 11c caused by the arrangement position of the light-emitting structure.

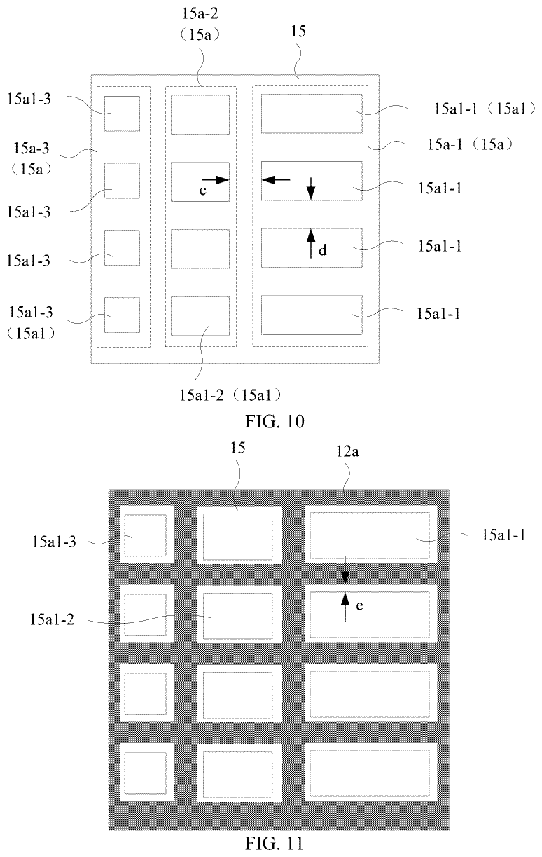

Optionally, the fourth spacing d is less than the third spacing c. Thus, the light-emitting sub-structure 1321 of the light-emitting structure 132 is arranged more compactly, and the light-emitting area of the light-emitting sub-structure 1321 is set to be larger. This is beneficial for maximizing the aperture ratio and minimizing the loss of the separated light-emitting structure 132 on the aperture ratio, ensuring the display effect. Optionally, a difference between the third spacing c and the fourth spacing d is greater than 0 μm and less than or equal to 16 μm. Exemplarily, the difference between the third spacing c and the fourth spacing d may be 0.1 μm, 1 μm, 3 μm, 5 μm, 8 μm, 12 μm, 14 μm, 16 μm, or any numeral value within the range of the above-mentioned numeral values. By making the difference between the third spacing c and the fourth spacing d fall within the above-mentioned range, it is beneficial for improving the aperture ratio and ensuring the display effect. Optionally, the third spacing c is greater than or equal to 10 μm and less than or equal to 20 μm. Exemplarily, the third spacing c may be 0.1 μm, 2 μm, 4 μm, 6 μm, 10 μm, 12 μm or any numeral value between two above-mentioned numeral values. By making the third spacing c fall within the above-mentioned range, it is beneficial for improving the aperture ratio and ensuring the display effect. Optionally, the fourth distance is greater than 0 μm and less than or equal to 12 μm. Exemplarily, the fourth spacing d may be 10 μm, 13 μm, 14 μm, 16 μm, 18 μm, 20 μm or any numeral value between two above-mentioned numeral values. By making the fourth spacing d fall within the above-mentioned range, it is beneficial for improving the aperture ratio and ensuring the display effect. As shown in FIG. 10, a spacing between two adjacent pixel openings 15a is the third spacing c. In the same pixel opening 15a, a spacing between two adjacent pixel sub-openings is the fourth spacing d.

Embodiments of the present disclosure provide a display panel 10, including an array substrate 11 and a plurality of light-emitting unit groups 17 arranged on the array substrate 11.

Furthermore, as shown in FIGS. 15 and 16, a light-emitting unit group 17 includes a plurality of light-emitting structures 132, and each of the plurality of light-emitting structures 132 includes a plurality of first light-emitting structures 132a, a plurality of second light-emitting structures 132b, and a plurality of third light-emitting structures 132c. Centroids of the plurality of first light-emitting structures 132a and the plurality of third light-emitting structures 132c, when connected, define a first virtual polygon N4, and at least one of the plurality of second light-emitting structure 132b is located in the first virtual polygon N4. The first light-emitting structure 132a, the second light-emitting structure 132b, and the third light-emitting structure 132c are configured to emit light of different colors. In the same light-emitting unit group 17, at least one light-emitting structure 132 includes a plurality of light-emitting sub-structures 1321 spaced apart, and the plurality of light-emitting sub-structures 1321 are electrically connected to the same driver circuit in the array substrate 11. As shown in FIG. 6, a spacing between two adjacent light-emitting structures 132 is a third spacing c. In the same light-emitting structure 132, a spacing between two adjacent light-emitting sub-structures 1321 is a fourth spacing d, and the third spacing c and the fourth spacing d are not equal.

In the display panel 10 provided by embodiments of the present disclosure, as the light-emitting structure 132 includes a plurality of light-emitting sub-structures and the plurality of light-emitting sub-structures 1321 is electrically connected to the same driver circuit, when a certain light-emitting sub-structure 1321 fails, it may not affect other light-emitting sub-structures 1321. The other light-emitting sub-structures 1321 may still emit light normally, thereby reducing the risk of display defects in the display panel 10. Furthermore, by making the fourth spacing d and the third spacing c unequal, it is beneficial for designers to adaptively adjust the positioning of the light-emitting structure 132 based on actual requirements. For example, when the fourth spacing d is smaller than the third spacing c, it is beneficial for maximizing the aperture ratio and minimizing the loss of separating light-emitting structure 132 on the aperture ratio; when the fourth spacing d is larger than the third spacing c, it is beneficial to set through-hole structures in the area between adjacent light-emitting sub-structures 1321 for connecting the anode and the driver circuit, thereby facilitating the designers to set the position of the through-hole structures based on actual requirements and reducing the restrictions on the setting position of the through-hole structures caused by the arrangement position of the light-emitting structure 132.

Embodiments of the present disclosure provide a display device, including the display panel 10 of the above-mentioned embodiments.

Various features of the above-mentioned embodiments may be combined in any way. To keep the description concise, not all possible combinations of the technical features in the above embodiments have been described. However, as long as the combinations of these features do not contradict each other, they should all be considered within the scope described in this specification.

What is claimed is:

1. A display panel, comprising
an array substrate;
an isolation layer located on a side of the array substrate, comprising an isolation structure and a plurality of isolation openings defined by the isolation structure; and
a plurality of light-emitting devices, comprising a plurality of first light-emitting devices arranged correspondingly to the plurality of first isolation openings, a plurality of second light-emitting devices arranged correspondingly to the plurality of second isolation openings, and a plurality of third light-emitting devices arranged correspondingly to the plurality of third isolation openings;
wherein the plurality of isolation openings comprise a plurality of first isolation openings, a plurality of second isolation openings, and a plurality of third isolation openings; the first light-emitting devices, the second light-emitting devices, and the third light-emitting devices are configured to emit light of different colors, and a light-emitting device comprises a first electrode, a light-emitting structure, and a second electrode sequentially stacked; the light-emitting structure of at least one of the plurality of light-emitting devices comprises a plurality of light-emitting sub-structures, the isolation layer comprises a partition wall located between adjacent light-emitting sub-structures, an orthogonal projection of the first electrode of the at least one of the plurality of light-emitting devices on the array substrate covers an orthogonal projection of the partition wall corresponding to the at least one of the plurality of light-emitting devices on the array substrate and orthogonal projections of the plurality of light-emitting sub-structures corresponding to the at least one of the plurality of light-emitting devices on the array substrate.

2. The display panel according to claim 1, wherein in the plurality of first light-emitting devices, the plurality of second light-emitting devices, and the plurality of third light-emitting devices, the light-emitting structure of the light-emitting device of at least one color comprises the plurality of light-emitting sub-structures; or
in the plurality of first light-emitting devices, the plurality of second light-emitting devices, and the plurality of third light-emitting devices, the light-emitting structure of the light-emitting device of at least two colors comprises the plurality of light-emitting sub-structures; or
the light-emitting structure of each of the plurality of light-emitting devices comprises the plurality of light-emitting sub-structures.

3. The display panel according to claim 1, wherein one of the plurality of isolation openings corresponding to at least one of the plurality of light-emitting devices comprises a plurality of sub-isolation openings, the partition wall is arranged between two adjacent sub-isolation openings; the plurality of sub-isolation openings are in one-to-one correspondence with the plurality of light-emitting sub-structures; in the orthogonal projection of the partition wall on the array substrate, a projection edge adjacent to one sub-isolation opening is parallel to a projection edge adjacent to another sub-isolation opening;
the array substrate comprises a plurality of scan lines spaced apart along a second direction, each of the plurality of scan lines extends along a first direction intersecting the second direction; an orthogonal projection of a sub-isolation opening on the array substrate comprises at least one projection edge parallel to the second direction; and
an orthogonal projection of each of the plurality of isolation openings on the array substrate comprises at least one projection edge parallel to the second direction.

4. The display panel according to claim 1, wherein one of the plurality of isolation openings corresponding to at least one of the plurality of light-emitting devices comprises a plurality of sub-isolation openings, the partition wall is arranged between two adjacent sub-isolation openings; the plurality of sub-isolation openings are in one-to-one correspondence with the plurality of light-emitting sub-structures; and
in a same isolation opening, areas of orthogonal projections of the plurality of sub-isolation openings on the array substrate are the same; or
in the same isolation opening, shapes of the orthogonal projections of the plurality of sub-isolation openings on the array substrate are the same; or
in the same isolation opening, orthogonal projections of two adjacent sub-isolation openings on the array substrate are arranged symmetrically relative to an axis; or
in the same isolation opening, the orthogonal projections of the two adjacent sub-isolation openings on the array substrate are arranged centrosymmetrically.

5. The display panel according to claim 1, wherein one of the plurality of isolation openings corresponding to at least one of the plurality of light-emitting devices comprises a plurality of sub-isolation openings, the partition wall is arranged between two adjacent sub-isolation openings; the plurality of sub-isolation openings are in one-to-one correspondence with the plurality of light-emitting sub-structures; and in a same isolation opening, areas of orthogonal projections of the plurality of sub-isolation openings on the array substrate are not equal;
the array substrate further comprises a first wiring line; in at least two of the plurality of sub-isolation openings, an orthogonal projection of at least one sub-isolation opening on the array substrate overlaps with an orthogonal projection of the first wiring line on the array substrate and an overlapping projection is arranged symmetrically about a centerline of the orthogonal projection of the at least one sub-isolation opening on the array substrate, and an orthogonal projection of at least one sub-isolation opening on the array substrate does not overlap with the orthogonal projection of the first wiring line on the array substrate.

6. The display panel according to claim 1, wherein a minimum distance between two adjacent isolation openings is a first spacing; one of the plurality of isolation openings corresponding to at least one of the plurality of light-emitting devices comprises a plurality of sub-isolation openings, the partition wall is arranged between two adjacent sub-isolation openings; the plurality of sub-isolation openings are in one-to-one correspondence with the plurality of light-emitting sub-structures; in a same isolation opening, a minimum distance between two adjacent sub-isolation openings is a second spacing; and
the first spacing is the same to the second spacing; or
the second spacing is less than the first spacing; or
a difference between the first spacing and the second spacing is greater than 0 μm and less than or equal to 16 μm.

7. The display panel according to claim 1, wherein the second electrodes of at least part of the plurality of light-emitting devices are electrically connected to the isolation layer; or
both the isolation structure and the partition wall comprise a conductive portion and a barrier portion stacked in a direction away from the array substrate, an orthogonal projection of the conductive portion on the array substrate is located within an orthogonal projection of the barrier portion on the array substrate; the second electrodes of at least part of the plurality of light-emitting devices are in contact with the conductive portion; or
the second electrode of at least one of the plurality of light-emitting devices comprises a plurality of sub-electrode portions in one-to-one correspondence with the plurality of light-emitting sub-structures, each of the plurality of sub-electrode portions is in contact with the conductive portion; at least a part of an outer edge of each of the plurality of sub-electrode portions covers a side wall, close to an isolation opening, of the conductive portion; and in a same light-emitting device, a maximum distance between the outer edge of each of the plurality of sub-electrode portions and the array substrate is the same; or
an orthogonal projection of the first electrode of at least one of the plurality of light-emitting devices on the array substrate covers an orthogonal projection of a surface, closer to the array substrate, of the barrier portion of the partition wall corresponding to the at least one of the plurality of light-emitting devices on the array substrate.

8. The display panel according to claim 1, further comprising a plurality of encapsulation portions in one-to-one correspondence with the plurality of light-emitting devices, each of the plurality of encapsulation portions disposed on a side, facing away from the array substrate, of a corresponding one of the plurality of light-emitting device, wherein
an orthogonal projection of one of the plurality of encapsulation portions corresponding to at least one of the plurality of light-emitting devices on the array substrate, covers an orthogonal projection of the partition wall corresponding to the at least one of the plurality of light-emitting devices on the array substrate and orthogonal projections of the plurality of light-emitting sub-structures corresponding to the at least one of the plurality of light-emitting device on the array substrate; and a light-emitting material layer and an electrode material layer stacked in sequence are further provided between the partition wall and the encapsulation portion; or
one of the plurality of encapsulation portions corresponding to at least one of the plurality of light-emitting devices comprises a plurality of sub-encapsulation portions spaced apart, the plurality of sub-encapsulation portions is in one-to-one correspondence with the plurality of light-emitting sub-structures, a sub-encapsulation portion is provided on a side, facing away from the array substrate, of a corresponding one of the plurality of light-emitting sub-structure; or
the display panel further comprises a pixel defining layer provided between the array substrate and the isolation layer and defining a plurality of pixel openings in one-to-one correspondence with the plurality of light-emitting devices, at least a part of each of the plurality of light-emitting devices is disposed in a corresponding one of the plurality of pixel opening; and one of the plurality of pixel openings corresponding to at least one of the plurality of light-emitting devices comprises a plurality of sub-pixel openings in one-to-one correspondence with the plurality of light-emitting sub-structures.

9. The display panel according to claim 1, wherein an inner wall of one the plurality of isolation opening comprises a first straight side parallel to a plane defined by the array substrate, the plurality of first isolation openings are arranged along a first direction to form a plurality of first isolation opening rows, the plurality of second isolation openings and the plurality of third isolation openings are alternately arranged along the first direction to form a plurality of second isolation opening rows, and the plurality of first isolation-opening rows and the plurality of second isolation-opening rows are alternately arranged along a second direction intersecting the first direction; adjacent second isolation opening and third isolation opening are located in a first virtual quadrilateral, the first straight side of at least one of the plurality of second isolation opening and the plurality of third isolation opening lies on an edge of the first virtual quadrilateral, and at least one of the plurality of first isolation opening is located in the first virtual quadrilateral;
a portion of an edge of the second electrode of each of the plurality of light-emitting devices is arranged on the first straight side; or
a second isolation opening is located at a first vertex of a second virtual quadrilateral, a third isolation openings is located at a second vertex of the second virtual quadrilateral, first vertices and second vertices are alternatively arranged and spaced apart; a first isolation opening is located in the second virtual quadrilateral, and a center of the first isolation opening is offset from a center of the second virtual quadrilateral; or
along the first direction, the second virtual quadrilateral comprises a first side and a second side opposite to each other, and a length of the first side is less than a length of the second side; and the first edge and the second edge are parallel to each other.

10. The display panel according to claim 1, wherein the plurality of first isolation openings, the plurality of second isolation openings, and the plurality of third isolation openings are arranged along a first direction to form a plurality of third isolation-opening rows, the plurality of third isolation-opening rows are sequentially arranged along a second direction intersecting the first direction; in a same third isolation-opening row, the plurality of first isolation openings, the plurality of second isolation openings, and the plurality of third isolation openings are alternately arranged in sequence; or
the array substrate comprises a plurality of scan lines spaced apart along the second direction, each of the plurality of scan lines extends along the first direction; an inner wall of one of the plurality of isolation openings comprises a first straight side parallel to the second direction; or
a length of one of the plurality of the first isolation openings, a length of one of the plurality of the second isolation openings, and a length of one of the plurality of the third isolation openings along the second direction are the same.

11. The display panel according to claim 1, wherein the plurality of first isolation openings and the plurality of second isolation openings are alternately arranged along a second direction to form a plurality of first isolation opening columns, the plurality of third isolation openings are arranged along the second direction to form a plurality of second isolation opening columns, the plurality of first isolation opening columns and the plurality of second isolation opening columns are alternately arranged along a first direction intersecting the second direction;
a first isolation opening comprises a plurality of first sub-isolation openings arranged along the first direction, the partition wall is arranged between two adjacent first sub-isolation openings; a second isolation openings comprises a plurality of second sub-isolation openings arranged along the first direction, the partition wall is arranged between two adjacent second sub-isolation openings; and a third isolation openings comprises a plurality of third sub-isolation openings arranged along the second direction, the partition wall is arranged between two adjacent third sub-isolation openings; or
an extending direction of the partition wall between the two adjacent first sub-isolation openings intersects an extending direction of the partition wall between the two adjacent third sub-isolation openings; and an extending direction of the partition wall between the two adjacent second sub-isolation openings intersects the extending direction of the partition wall between the two adjacent third sub-isolation openings; or
the first isolation opening comprises two first sub-isolation openings, the second isolation opening comprises two second sub-isolation openings, and the third isolation opening comprises two third sub-isolation openings.

12. The display panel according to claim 1, wherein a wavelength of light emitted by each of the plurality of first light-emitting devices ranges from 505 nm to 545 nm, a wavelength of light emitted by each of the plurality of second light-emitting device ranges from 600 nm to 650 nm, and a wavelength of light emitted by each of the plurality of third light-emitting device ranges from 440 nm to 480 nm;
a light-emitting structure of the second light-emitting device comprises a plurality of light-emitting sub-structures, and a second isolation opening comprises a plurality of second sub-isolation openings; a shape of an orthogonal projection of a second sub-isolation opening on the array substrate is a polygon; or
the light-emitting structure of the second light-emitting device comprises two light-emitting sub-structures, and the second isolation opening comprises two second sub-isolation openings; or the light-emitting structure of the second light-emitting device comprises four light-emitting sub-structures, and the second isolation opening comprises four second sub-isolation openings; and centroids of orthogonal projections of the four second sub-isolation openings on the array substrate, when connected, define a quadrilateral; or
a light-emitting structure of the first light-emitting device comprises a plurality of light-emitting sub-structures, and a first isolation opening comprises a plurality of first sub-isolation openings; and a shape of an orthogonal projection of a first sub-isolation opening on the array substrate is a polygon; or
the light-emitting structure of the first light-emitting device comprises two light-emitting sub-structures, and the first isolation opening comprises two first sub-isolation openings; or the light-emitting structure of the first light-emitting device comprises four light-emitting sub-structures, and the first isolation opening comprises four first sub-isolation openings; centroids of orthogonal projections of the four first sub-isolation openings on the array substrate, when connected, define a quadrilateral; or
a light-emitting structure of the third light-emitting device comprises a plurality of light-emitting sub-structures, and a third isolation openings comprises a plurality of third sub-isolation openings; and a shape of an orthogonal projection of a third sub-isolation opening on the array substrate is a polygon; or
the light-emitting structure of the third light-emitting device comprises two light-emitting sub-structures, and the third isolation opening comprises two third sub-isolation openings; or the light-emitting structure of the third light-emitting device comprises four light-emitting sub-structures, and the third isolation opening comprises four third sub-isolation openings; and
centroids of orthogonal projections of the four third sub-isolation openings on the array substrate, when connected, define a quadrilateral.

13. A display panel, comprising:
an array substrate;
a plurality of light-emitting unit groups provided on the array substrate; wherein a light-emitting unit group comprises a plurality of light-emitting structures, the plurality of light-emitting structures comprise a plurality of first light-emitting structures, a plurality of second light-emitting structures, and a plurality of third light-emitting structures, centroids of the plurality of second light-emitting structures and the plurality of third light-emitting structures, when connected, define a first virtual polygon, at least one of the plurality of first light-emitting structure is located in the first virtual polygon; the first light-emitting structures, the second light-emitting structures, and the third light-emitting structures are configured to emit light of different colors; and
in a same light-emitting unit group, at least one of the plurality of light-emitting structures comprises a plurality of light-emitting sub-structures spaced apart, and the plurality of light-emitting sub-structures are electrically connected to a same driver circuit in the array substrate.

14. The display panel according to claim 13, wherein in the same light-emitting unit group, one of the plurality of light-emitting structures of at least one color comprises the plurality of light-emitting sub-structures spaced apart;
in the same light-emitting unit group, one of the plurality of light-emitting structures of at least two colors comprises the plurality of light-emitting sub-structures spaced apart; or
in the same light-emitting unit group, each of the plurality of light-emitting structures comprises the plurality of light-emitting sub-structures spaced apart.

15. The display panel according to claim 13, wherein in a same light-emitting structure, adjacent sides of two adjacent light-emitting sub-structures are straight sides and are parallel to each other; or
the array substrate comprises a plurality of scan lines spaced apart along a second direction, each of the plurality of scan lines extends along a first direction intersecting the second direction; a light-emitting sub-structure comprises at least one straight side parallel to the second direction; and
each of the plurality of light-emitting structures comprises at least one straight side parallel to the second direction.

16. The display panel according to claim 13, wherein in a same light-emitting structure, areas of the plurality of light-emitting sub-structures are the same;
in the same light-emitting structure, shapes of the plurality of light-emitting sub-structures are the same;
in the same light-emitting structure, two adjacent light-emitting sub-structures are arranged axisymmetrically, or in the same light-emitting structure, the two adjacent light-emitting sub-structures are arranged centrosymmetrically; or
areas of at least two light-emitting sub-structures of at least one of the plurality of light-emitting structures are not equal; or
the array substrate further comprises a first wiring line, in the at least two light-emitting sub-structures, an orthogonal projection of at least one light-emitting sub-structure on the array substrate overlaps with an orthogonal projection of the first wiring line on the array substrate and an overlapping projection is arranged symmetrically about a centerline of the orthogonal projection of the at least one light-emitting sub-structure on the array substrate, and the orthogonal projection of at least one light-emitting sub-structure on the array substrate does not overlap with the orthogonal projection of the first wiring line on the array substrate.

17. The display panel according to claim 13, wherein a partition wall is provided between adjacent light-emitting sub-structures, the display panel further comprises a plurality of first electrodes in one-to-one correspondence with the plurality of light-emitting structures, a first electrode is disposed between a corresponding one of the plurality of light-emitting structures and the array substrate; and
the first electrode corresponding to a light-emitting structure comprising the plurality of light-emitting sub-structures comprises a plurality of sub-electrodes, the plurality of sub-electrodes are in one-to-one correspondence with the plurality of light-emitting sub-structures; in a same first electrode, adjacent sub-electrodes are connected by a connection line;
the display panel further comprises a plurality of conductive structures corresponding to the plurality of first electrodes, each of the plurality of first electrodes is electrically connected to a corresponding driver circuit through at least one of the plurality of conductive structures;
at least one of the plurality of light-emitting structures comprises two light-emitting sub-structures, and the first electrode corresponding to the light-emitting structure comprises two sub-electrodes connected by the connection line; a conductive structure is located between two sub-electrodes and is connected to the connection line; or, the conductive structure is connected to a side, facing away from another sub-electrode, of one sub-electrode;
at least part of an orthogonal projection of the connection line on the array substrate is located in an orthogonal projection of the partition wall on the array substrate; or
at least one of the plurality of light-emitting structures comprises four light-emitting sub-structures, the first electrode corresponding to the light-emitting structure comprises four sub-electrodes, and each of the plurality of sub-electrodes is directly connected to the at least one connection line;
centroids of the four sub-electrodes, when connected, define a third virtual quadrilateral;
the four sub-electrodes are electrically connected to corresponding driver circuits by the conductive structure;
the conductive structure is located inside the third virtual quadrilateral, and each sub-electrode is connected to the conductive structure through one of the at least one connection line;
the third virtual quadrilateral comprises a first corner, a second corner, a third corner and a fourth corner, the conductive structure is located outside the third virtual quadrilateral and is connected to the sub-electrode at the first corner, the connection line is provided between the sub-electrode at the first corner and the sub-electrode at the second corner, the connection line is provided between the sub-electrode at the second corner and the sub-electrode at the third corner, and the connection line is provided between the sub-electrode at the third corner and the sub-electrode at the fourth corner; or
the third virtual quadrilateral comprises the first corner, the second corner, the third corner and the fourth corner; the conductive structure is located outside the third virtual quadrilateral, the sub-electrode at the first corner and the sub-electrode at the fourth corner are connected to the conductive structure respectively; the connection line is provided between the sub-electrode at the first corner and the sub-electrode at the second corner, and the connection line is provided between the sub-electrode at the third corner and the sub-electrode at the fourth corner; and the connection line is provided between the sub-electrode at the second corner and the sub-electrode at the third corner; or
the third virtual quadrilateral comprises the first corner, the second corner, the third corner and the fourth corner, the sub-electrode at the first corner and the sub-electrode at the fourth corner are connected to the conductive structure, and the conductive structure is located between the two sub-electrodes; and the connection line is provided between the sub-electrode at the first corner and the sub-electrode at the second corner, and the connection line is provided between the sub-electrode at the third corner and the sub-electrode at the fourth corner.

18. The display panel according to claim 13, wherein a partition wall is provided between adjacent light-emitting sub-structures, the display panel further comprises a plurality of first electrodes in one-to-one correspondence with the plurality of light-emitting structures, and one of the plurality of first electrodes is arranged between a corresponding one of the plurality of light-emitting structure and the array substrate; and
an orthogonal projection of a first electrode corresponding to the light-emitting structure comprising the plurality of light-emitting sub-structures on the array substrate, covers orthogonal projections of the plurality of light-emitting sub-structures corresponding to the light-emitting structure on the array substrate and an orthogonal projection of the partition wall corresponding to the light-emitting structure on the array substrate;
the first electrode corresponding to a first light-emitting structure comprises a first main body portion, and orthogonal projections of a plurality of first light-emitting sub-structures of the first light-emitting structure on the array substrate are located within an orthogonal projection of the first main body portion on the array substrate;
the first main body portion is electrically connected to the driver circuit in the array substrate through a conductive structure;
the first electrode further comprises a first protruding portion connected to the first main body portion, and the first protruding portion is electrically connected to the driver circuit in the array substrate through the conductive structure; and
an orthogonal projection of the first protruding portion on the array substrate is located in an orthogonal projection of the isolation structure on the array substrate.

19. The display panel according to claim 17, wherein the display panel further comprises an isolation layer provided on the array substrate, the isolation layer comprises an isolation structure and a plurality of opening groups, an opening group comprises a plurality of isolation openings, the plurality of isolation openings comprise a plurality of first isolation openings, a plurality of second isolation openings, and a plurality of third isolation openings, the plurality of first light-emitting structures is in one-to-one correspondence with the plurality of first isolation openings, the plurality of second light-emitting structures is in one-to-one correspondence with the plurality of second isolation openings, and the plurality of third light-emitting structures is in one-to-one correspondence with the plurality of third isolation openings; at least part of one of the plurality of the light-emitting structure is disposed in a corresponding one of the plurality of isolation opening; the isolation layer further comprises the partition wall located between adjacent light-emitting sub-structures;
the isolation structure is provided with a via hole corresponding to a connection line, and an orthogonal projection of a hole wall of the via hole on the array substrate overlaps an orthogonal projection of the connection line corresponding to the via hole on the array substrate; or, an orthogonal projection of a metal layer in the array substrate does not overlap at least part of the orthogonal projection of the connection line; or
the display panel further comprises a plurality of second electrodes in one-to-one correspondence with the plurality of light-emitting structures, one of the plurality of second electrodes is arranged on a side, facing away from the array substrate, of a corresponding one of the plurality of light-emitting structure, and is electrically connected to the isolation structure;
the isolation structure comprises a conductive portion and a barrier portion stacked in a direction away from the array substrate, an orthogonal projection of the conductive portion on the array substrate is located within an orthogonal projection of the barrier portion on the array substrate; at least part of the plurality of second electrodes is in contact with the conductive portion;
one of the plurality of second electrodes corresponding to the light-emitting structure comprising the plurality of light-emitting sub-structures comprises a plurality of sub-electrode portions in one-to-one correspondence with the plurality of light-emitting sub-structures, each of the plurality of sub-electrode portions is in contact with the conductive portion;
at least part of an outer edge of each of the plurality of sub-electrode portions covers a side wall, close to the isolation opening, of the conductive portion;
in a same light-emitting device, a maximum distance between the outer edge of each of the plurality of sub-electrode portions and the array substrate is the same;
the display panel further comprises a plurality of first encapsulation portions arranged in one-to-one correspondence with the plurality of first light-emitting structures, and one of the plurality of first encapsulation portions is arranged on a side, facing away from the array substrate, of a corresponding one of the plurality of first light-emitting structure;
an orthogonal projections of one of the plurality of first encapsulation portions on the array substrate covers orthogonal projections of the plurality of first light-emitting sub-structures corresponding to the first light-emitting structure on the array substrate and an orthogonal projection of the partition wall corresponding to the first light-emitting structure on the array substrate;
a light-emitting material layer and an electrode material layer stacked are further provided between the partition wall located between two adjacent first light-emitting sub-structures and the first encapsulation portion;
a first encapsulation portion comprises a plurality of first sub-encapsulation portions spaced apart, the plurality of first sub-encapsulation portions are in one-to-one correspondence with the plurality of first light-emitting sub-structures, and one of the plurality of first sub-encapsulation portions is arranged on a side, facing away from the array substrate, of a corresponding one of the plurality of first light-emitting sub-structure;
the display panel further comprises a plurality of second encapsulation portions arranged in one-to-one correspondence with the plurality of second light-emitting structures, one of the plurality of second encapsulation portions is arranged on a side, facing away from the array substrate, of a corresponding one of the plurality of second light-emitting structures;
an orthogonal projection of a second encapsulation portion on the array substrate covers orthogonal projections of the plurality of second light-emitting sub-structures corresponding to the second light-emitting structure on the array substrate and an orthogonal projection of the partition wall corresponding to the second light-emitting structure on the array substrate;
the light-emitting material layer and the electrode material layer stacked are further provided between the partition wall located between two adjacent second light-emitting sub-structures, and the second encapsulation portion;
the second encapsulation portion comprises a plurality of second sub-encapsulation portions spaced apart, the plurality of second sub-encapsulation portions are in one-to-one correspondence with the plurality of second light-emitting sub-structures, and one of the plurality of second sub-encapsulation portions is arranged on a side, facing away from the array substrate, of a corresponding one of the plurality of second light-emitting sub-structure;
the display panel further comprises a plurality of third encapsulation portions arranged in one-to-one correspondence with the plurality of third light-emitting structures, and one of the plurality of third encapsulation portions is arranged on a side, facing away from the array substrate, of a corresponding one of the plurality of third light-emitting structure;
an orthogonal projections of a third encapsulation portion on the array substrate covers orthogonal projections of the plurality of third light-emitting sub-structures corresponding to the third light-emitting structure on the array substrate and an orthogonal projection of the partition wall corresponding to the third light-emitting structure on the array substrate;
the light-emitting material layer and the electrode material layer stacked are further arranged between the partition wall located between two adjacent third light-emitting sub-structures, and the third encapsulation portion; and
the third encapsulation portion comprises a plurality of third sub-encapsulation portions spaced apart arranged in one-to-one correspondence with the plurality of third light-emitting sub-structures, and one of the plurality of third sub-encapsulation portions is arranged on a side, facing away from the array substrate, of a corresponding one of the plurality of third light-emitting sub-structure.

20. A display device, comprising:
a display panel, comprising:
an array substrate;
an isolation layer located on a side of the array substrate, comprising an isolation structure and a plurality of isolation openings defined by the isolation structure; and
a plurality of light-emitting devices, comprising a plurality of first light-emitting devices arranged correspondingly to the plurality of first isolation openings, a plurality of second light-emitting devices arranged correspondingly to the plurality of second isolation openings, and a plurality of third light-emitting devices arranged correspondingly to the plurality of third isolation openings;
wherein the plurality of isolation openings comprise a plurality of first isolation openings, a plurality of second isolation openings, and a plurality of third isolation openings; the first light-emitting devices, the second light-emitting devices, and the third light-emitting devices are configured to emit light of different colors, and a light-emitting device comprises a first electrode, a light-emitting structure, and a second electrode sequentially stacked; the light-emitting structure of at least one of the plurality of light-emitting devices comprises a plurality of light-emitting sub-structures, the isolation layer comprises a partition wall located between adjacent light-emitting sub-structures, an orthogonal projection of the first electrode of the at least one of the plurality of light-emitting devices on the array substrate covers an orthogonal projection of the partition wall corresponding to the at least one of the plurality of light-emitting devices on the array substrate and orthogonal projections of the plurality of light-emitting sub-structures corresponding to the at least one of the plurality of light-emitting devices on the array substrate.
